(19) United States
(12) Patent Application Publication
(10) Pub. No.: US 2025/0029556 A1
(43) Pub. Date: Jan. 23, 2025

(54) DISPLAY DEVICE

(71) Applicant: LG Display Co., Ltd., Seoul (KR)

(72) Inventors: SeongHo CHO, Gumi-si (KR); SangMoo SONG, Seoul (KR); YoungKyu SHIN, Chilgok-gun (KR); Solip JU, Gumi-si (KR)

(73) Assignee: LG Display Co., Ltd., Seoul (KR)

(21) Appl. No.: 18/777,028

(22) Filed: Jul. 18, 2024

(30) Foreign Application Priority Data
Jul. 21, 2023 (KR) 10-2023-0095457

(51) Int. Cl. G09G 3/3225

(52) U.S. Cl. CPC G09G 3/3225; G09G 2300/0842; G09G 2300/0861; G09G 2320/068; G09G 2320/08; G09G 2358/00; G09G 2370/00; G09G 2380/10

(57) ABSTRACT

A display device can include a plurality of pixel blocks, each of the plurality of pixel blocks including a plurality of pixels, a plurality of mux parts disposed to correspond to columns of the plurality of pixel blocks, a first level shift configured to transmit a first mode signal or a second mode signal to the plurality of mux parts, a second level shift configured to transmit a plurality of mux signals to the plurality of mux parts, and a mode controller configured to control the first level shift and the second level shift.

### CROSS-REFERENCE TO RELATED APPLICATIONS

This application claims priority to Korean Patent Application No. 10-2023-0095457 filed in the Republic of Korea, on Jul. 21, 2023, the entirety of which is incorporated herein by reference into the present application.

### BACKGROUND

### Field

The present specification relates to a display device, and more particularly, to a display device capable of controlling a viewing angle.

### Description of the Related Art

With the advancement of technologies in the modern society, display devices are being used in various ways to provide information to users. The display devices can be included in electronic display boards, which simply transfer visual information in one direction, and also included in various high-technology electronic devices that identify user inputs and provide information in response to the identified inputs.

For example, the display device can be included in a vehicle and provide various information to a driver and a fellow passenger in the vehicle. However, the display device in the vehicle may display content or cause bright lights inside the vehicle that distract the driver which can impair safety. Thus, there exists a need for a display device that is capable of selectively controlling the viewing angle and restricting displayed content in order to avoid interfering with the driver's concentration and improve safety.

### SUMMARY OF THE DISCLOSURE

An object to be achieved by the present disclosure is to provide a display device capable of selectively controlling viewing angles of a plurality of areas in both a row direction and a column direction.

Another object to be achieved by the present disclosure is to provide a display device capable of minimizing the number of lines configured to transmit control signals for controlling viewing angles of a plurality of areas.

Objects of the present disclosure are not limited to the above-mentioned objects, and other objects, which are not mentioned above, can be clearly understood by those skilled in the art from the following descriptions.

In one aspect of the present disclosure, there is provided a display device including a plurality of pixel blocks each including a plurality of pixels, a plurality of mux parts disposed to correspond to a column of each of the plurality of pixel blocks, a first level shift configured to transmit a first mode signal or second mode signal related to mode of the plurality of pixel blocks to the plurality of mux parts, a second level shift configured to transmit a plurality of mux signals to the plurality of mux parts, and a mode controller configured to control the first level shift and the second level shift.

In another aspect of the present disclosure, there is provided a display device including a plurality of pixel blocks each including a plurality of pixels and disposed in m rows and n columns, first to n-th mux parts disposed to correspond to the column of each of the plurality of pixel blocks, a first level shift configured to transmit a first mode signal or second mode signal related to mode of the plurality of pixel blocks to the first to n-th mux parts, a second level shift configured to transmit first to m-th mux signals to the first to n-th mux parts, and a mode controller configured to control the first level shift and the second level shift, in which n and m are positive integers.

Other detailed matters of the example embodiments are included in the detailed description and the drawings.

The display device according to one or more embodiments of the present specification can selectively control the viewing angles of the plurality of areas in both the row direction and the column direction, which can improve a degree of freedom related to viewing angle control.

The display device according to an embodiment of the present specification can minimize the number of control signals for controlling the viewing angles of the plurality of areas. Therefore, it is possible to provide the high-efficiency, low-power display device with reduced power consumption.

The effects according to the present disclosure are not limited to the examples discussed above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an example view illustrating a display device according to an embodiment of the present disclosure;

FIG. 2 is a functional block diagram of the display device according to an embodiment of the present disclosure;

FIG. 3 is a circuit diagram illustrating an example of a pixel circuit of the display device according to an embodiment of the present disclosure;

FIG. 4 is a circuit diagram illustrating an example of the pixel circuit of the display device according to an embodiment of the present disclosure;

FIG. 5 is an enlarged top plan view illustrating the arrangement of lenses included in the display device according to an embodiment of the present disclosure;

FIG. 6 is a cross-sectional view taken along line I-I′ in FIG. 5 according to an embodiment of the present disclosure;

FIG. 7 is a cross-sectional view taken along line II-II′ in FIG. 5 according to an embodiment of the present disclosure;

FIG. 8 is a schematic top plan view of a display device according to an embodiment of the present disclosure;

FIG. 9 is a top plan view illustrating one operational example of the display device according to an embodiment of the present disclosure;

FIG. 10 is a timing diagram for explaining an operational example of the display device according to an embodiment of the present disclosure;

FIG. 11 is a top plan view illustrating another operational example of the display device according to an embodiment of the present disclosure; and

FIG. 12 is a timing diagram for explaining still another operational example of the display device according to an embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure. Also, the term “can” used herein includes all meanings and definitions of the word “may.”

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

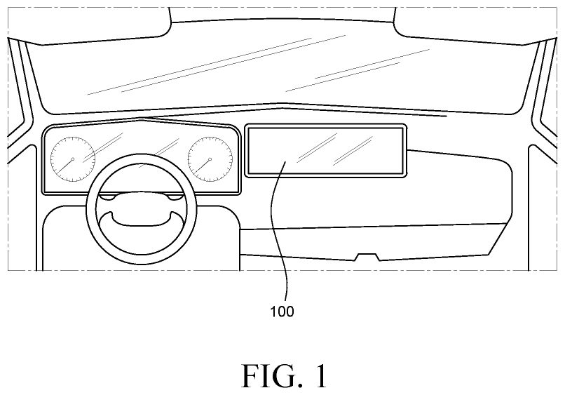

FIG. 1 is an example view illustrating a display device according to an embodiment of the present specification.

A display device 100 can be disposed on at least a part of a dashboard of a vehicle. The dashboard of the vehicle includes a configuration disposed at a front side of a front seat (e.g., a driver seat or a passenger seat) of the vehicle. For example, the dashboard of the vehicle can be equipped with an input configuration for manipulating various functions (e.g., an air conditioner, an audio system, and a navigation system) in the vehicle.

In an embodiment, the display device 100 can be disposed on the dashboard of the vehicle and operate as an input part for manipulating at least some of various functions of the vehicle. The display device 100 can provide various types of information related to the vehicle, e.g., driving information of the vehicle (e.g., a current speed of the vehicle, a remaining fuel amount, and a traveling distance), and information on components of the vehicle (e.g., a degree of damage to a vehicle tire).

In the embodiment, the display device 100 can be disposed to traverse the driver seat and the passenger seat disposed as the front seat of the vehicle. For example, the display device 100 can be in front of the driver's seat and the front passenger seat, but embodiments are not limited thereto. Users of the display device 100 can include a driver of the vehicle, and a fellow passenger seated in the passenger seat. Both the driver and the fellow passenger in the vehicle can use the display device 100.

In an embodiment, only a part of the display device 100 may be illustrated in FIG. 1. The display device 100 illustrated in FIG. 1 can be illustrated as a display panel among various components included in the display device 100. Specifically, for example, the display device 100 illustrated in FIG. 1 can be illustrated as at least a part of a display area and at least a part of a non-display area of the display panel. The components, which exclude the components illustrated in FIG. 1 among the components of the display device 100, can be mounted in the vehicle (or at least a part of the vehicle).

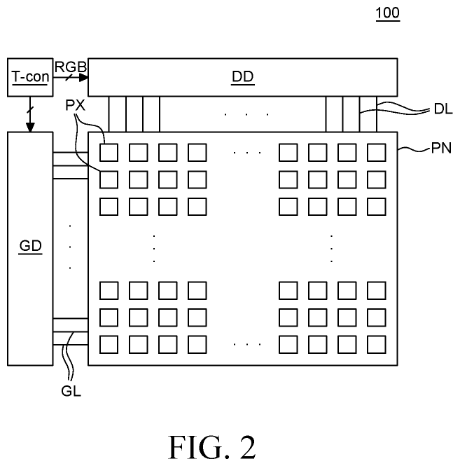

FIG. 2 is a functional block diagram of the display device according to an embodiment of the present disclosure.

An electroluminescent display device can be applied as the display device according to the embodiment of the present disclosure. An organic light-emitting diode display device, a quantum-dot light-emitting diode display device, or an inorganic light-emitting diode display device can be used as the electroluminescent display device.

With reference to FIG. 2, the display device 100 can include a display panel PN, a data drive circuit DD, a gate drive circuit GD, and a timing controller T-con.

In an embodiment, the display panel PN can create an image to be provided to the user. For example, the display panel PN can create and display images, which are to be provided to the user, through a plurality of pixels PX in which pixel circuits are disposed.

The data drive circuit DD, the gate drive circuit GD, and the timing controller T-con can provide signals for operating the pixels PX through signal lines. For example, the signal lines can include data lines DL and gate lines GL.

In some instances, the display device can further include a power source unit. In this situation, the signal for operating the pixel PX can be provided through a power line that connects the power source unit and the display panel PN. According to the embodiment, the power source unit can provide power to the data drive circuit DD and the gate drive circuit GD. The data drive circuit DD and the gate drive circuit GD can operate based on of power provided from the power source unit.

For example, the data drive circuit DD can apply data signals to the pixels PX through the data lines DL, the gate drive circuit GD can apply gate signals to the pixels PX through the gate lines GL, and the power source unit can supply power voltages to the pixels PX through power voltage supply lines.

The timing controller T-con can control the data drive circuit DD and the gate drive circuit GD. For example, the timing controller T-con can realign digital video data, which are input from the outside, to fit the resolution of the display panel PN and supply the video data to the data drive circuit DD.

The data drive circuit DD can convert digital video data, which are input from the timing controller T-con, into analog data voltages in response to the data control signal and supply the analog data voltages to the plurality of data lines.

The gate drive circuit GD can generate a scan signal and a light-emitting signal (or light emission control signal) in response to the gate control signal. The gate drive circuit GD can include a scan drive part and a light-emitting signal drive part. The scan drive part can generate scan signals in a row-sequential manner to operate at least one scan line connected to each pixel row and supply the scan signals to the scan lines. The light-emitting signal drive part can generate light-emitting signals in a row-sequential manner to operate at least one light-emitting signal line connected to each pixel row and supply the light-emitting signals to the light-emitting signal lines.

According to an embodiment, the gate drive circuit GD can be disposed on the display panel PN in a gate-driver-in-panel (GIP) manner. For example, the gate drive circuit GD can be divided into a plurality of gate drivers and respectively disposed on at least two side surfaces of the display panel PN.

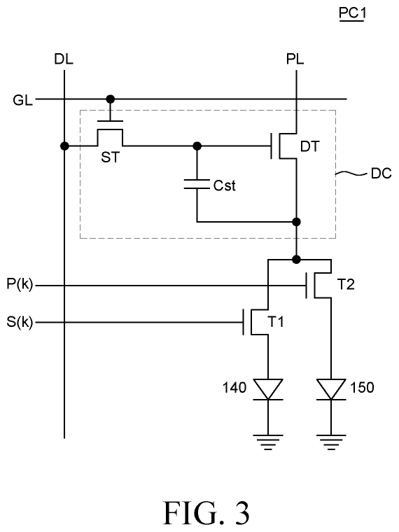

The display area of the display panel PN can include the plurality of pixels PX. In the pixel PX, the plurality of data lines (e.g., the data lines DL in FIG. 3) and the plurality of gate lines (e.g., the gate lines GL in FIG. 3) intersect, and subpixels can be disposed in each intersection area. The subpixels included in one pixel PX can emit light with different colors. For example, the pixel PX can implement blue, red, and green by using three subpixels. However, the present specification is not limited thereto. In some instances, the pixel PX can further include a subpixel for further implementing a particular color (e.g., white).

In the pixel PX, the area for implementing blue can be referred to as a blue subpixel, an area for implementing red can be referred to as a red subpixel, and an area for implementing green can be referred to as a green subpixel.

In an embodiment, the pixel PX can include a plurality of subpixels. The plurality of subpixels can each be divided into first and second lens areas that provide different viewing angles. For example, one pixel PX can include a first lens area configured to define a first viewing angle by providing light within a first range, and a second lens area configured to define a second viewing angle by providing light within a second range. The first range can correspond to a range larger than the second range.

The non-display area can be disposed along a periphery of the display area. Various constituent elements for operating the pixel circuit disposed in the pixel PX can be disposed in the non-display area. For example, at least a part of the gate drive circuit GD can be disposed in the non-display area. The non-display area can be referred to as a bezel area.

FIG. 3 is a circuit diagram illustrating an example of the pixel circuit of the display device according to the embodiment of the present specification. The pixel PX can include the plurality of subpixels for implementing different colors, and the pixel circuits PC1 respectively corresponding to the plurality of subpixels. FIG. 3 illustrates an example of the pixel circuit PC1 of one subpixel disposed in the pixel PX.

With reference to FIG. 3, the pixel circuit PC1 can include a plurality of transistors DT, ST, T1, and T2, a capacitor Cst, and a plurality of light-emitting elements 140 and 150.

A driving transistor DT and the capacitor Cst can be connected to a switching transistor ST. A first electrode of the driving transistor DT can be connected to a power voltage supply line PL.

The switching transistor ST can be connected to the gate line GL and supplied with the gate signal. The switching transistor ST can be turned on or off by the gate signal. A first electrode of the switching transistor ST can be connected to the data line DL. In this situation, the data signal can be supplied to a gate electrode of the driving transistor DT through the switching transistor ST based on that the switching transistor ST is turned on.

The capacitor Cst can be disposed between a gate electrode and the second electrode of the driving transistor DT. The capacitor Cst can maintain a signal applied to the gate electrode of the driving transistor DT, for example, maintain the data signal for one frame.

According to an embodiment, the driving transistor DT, the switching transistor ST, and the capacitor Cst can be constituent elements for operating light-emitting operations of the light-emitting elements (e.g., a first light-emitting element 140 and a second light-emitting element 150) and referred to as a drive part. However, the present disclosure is not limited by these terms.

The first light-emitting element 140 can be connected to a first transistor T1 that is turned on or off by a first mode signal S(k) (e.g., S mode, or share viewing mode having a wide angle). The second light-emitting element 150 can be connected to a second transistor T2 that is turned on or off by a second mode signal P(k) (e.g., P mode, or privacy viewing mode having a narrow viewing angle).

In this situation, the first light-emitting element 140 or the second light-emitting element 150 can be connected to other components of the pixel circuit PC1, e.g., the driving transistor DT in accordance with a mode. The mode can be determined based on a certain condition being satisfied, which can designated by a user's input or designated in advance. For example, in a situation of a predesignated first condition being satisfied, the first light-emitting element 140 emits light based on of the supply of the first mode signal S(k). In a situation of a predesignated second condition being satisfied, the second light-emitting element 150 can emit light based on of the supply of the second mode signal P(k). The first condition can include a predesignated condition for an operation to a first mode (e.g., S mode, or share viewing mode having a wide angle). The second condition can include a predesignated condition for an operation to a second mode (e.g., P mode, or privacy viewing mode having a narrow viewing angle).

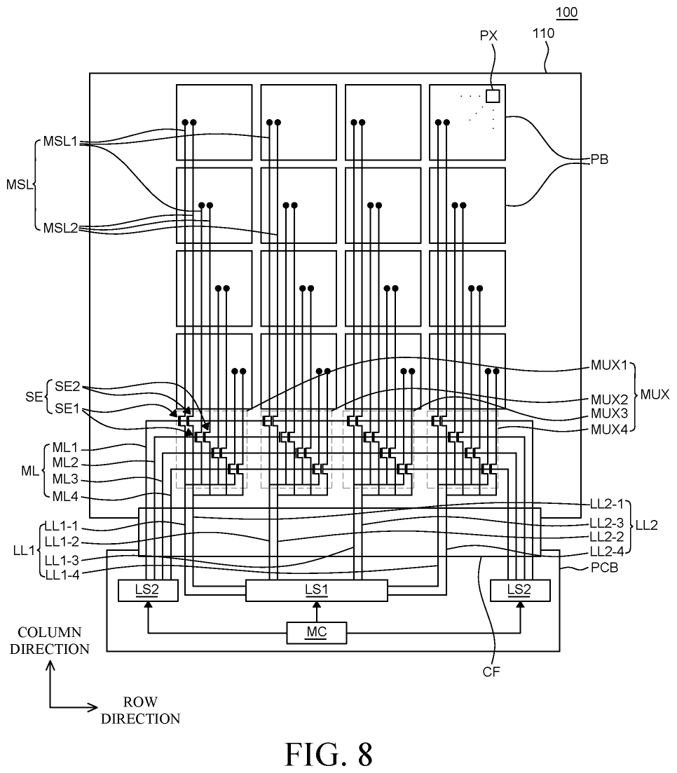

In this situation, at least one of the first mode signal S(k) and the second mode signal P(k) can be a light-emitting signal provided from the gate drive circuit. However, embodiments of the present disclosure are not limited thereto. At least one of the first mode signal S(k) and the second mode signal P(k) can be provided from a separate component. For example, at least one of the first mode signal S(k) and the second mode signal P(k) can be provided by a mode controller MC (e.g., mode control part, mode selector, or mode selector circuit) in FIG. 8 to be described below. The mode controller MC can also be referred to as a controller. Also, according to an embodiment, the mode controller MC, the first level shift LS1, the second level shift LS2 and the mux parts ML can collectively be referred to as a controller, but embodiments are not limited thereto.

In an embodiment, when the first mode signal S(k) is input as a low value, the first mode signal S(k) can allow the pixel circuit to operate in the first mode. When the second mode signal P(k) is input as a low value, the second mode signal P(k) can allow the pixel circuit to operate in a second mode.

The plurality of transistors DT, ST, T1, and T2 in FIG. 3 can include at least one of oxide semiconductors such as amorphous silicon, polycrystalline silicon, and IGZO. The first or second electrode of the transistor can be a source electrode or a drain electrode. For example, the first electrode can be a source electrode, or the second electrode can be a drain electrode. As another example, the first electrode can be a drain electrode, and the second electrode can be a source electrode.

Meanwhile, a pixel array having a plurality of horizontal pixel lines can be implemented on the display panel (e.g., the display panel PN in FIG. 2). The plurality of pixels PX, which are adjacent to one another horizontally and connected in common to the gate lines GL, can be disposed in each of the plurality of horizontal pixel lines.

In this situation, each of the horizontal pixel lines can mean a single line implemented by the plurality of pixels PX adjacent to one another horizontally. The pixel array can include a first power line configured to supply a high-potential power voltage to the pixel PX, and a second power line configured to supply a reference voltage to the pixel PX. In addition, the plurality of pixels PX can be connected to a low-potential power voltage.

In the embodiment, the gate line GL can include a scan line configured to supply a scan signal. In some instances, the gate line GL can include a first mode signal line configured to supply the first mode signal S(k), and a second mode signal line configured to supply the second mode signal P(k). However, the first mode signal line and the second mode signal line can be implemented as separate lines. However, the present disclosure is not limited thereto.

The pixel PX can include a plurality of subpixels configured to emit light beams with at least one color. For example, the subpixel can emit any one of red light, green light, blue light, and white light. The plurality of subpixels can constitute one pixel PX. The color implemented by one pixel PX can be determined depending on light-emitting ratios between red light, green light, blue light, and white light. The data line DL, the scan line, the first mode signal line, and the second mode signal line can be connected to each of the plurality of pixels PX.

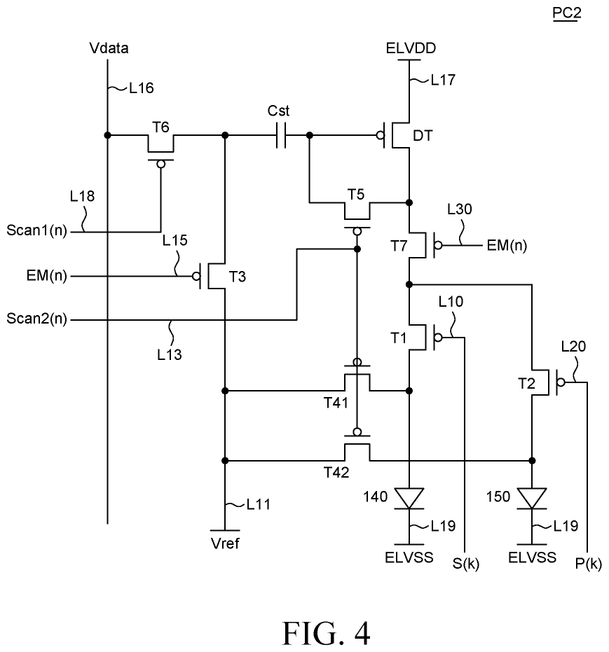

FIG. 4 is a circuit diagram illustrating an example of the pixel circuit of the display device according to an embodiment of the present disclosure. Specifically, FIG. 4 illustrates another example of the pixel circuit different from that in FIG. 3.

With reference to FIG. 4, a pixel circuit PC2 can include nine transistors and one capacitor.

The pixel circuit PC2 can include the first transistor T1, the second transistor T2, a third transistor T3, a fourth-first transistor T41, a fourth-second transistor T42, a fifth transistor T5, a sixth transistor T6, a seventh transistor T7, the driving transistor DT, and the capacitor Cst.

At least some of the nine transistors included in the pixel circuit PC2 can be an n-type transistor or a p-type transistor. In the situation of the p-type transistor, a low-level voltage of each of the driving signals can mean a voltage that turns on the TFT, and a high-level voltage of each of the driving signals can mean a voltage that turns off the TFTs.

In this situation, the low-level voltage can correspond to a predesignated voltage lower than the high-level voltage. For example, the low-level voltage can include a voltage corresponding to a range of −8 V to −12 V. The high-level voltage can correspond to a predesignated voltage higher than the low-level voltage. For example, the high-level voltage can include a voltage corresponding to a range of 12 V to 16 V. According to the embodiment, the low-level voltage can be referred to as a first voltage, and the high-level voltage can be referred to as a second voltage. In this situation, the first voltage can have a lower value than the second voltage.

The first or second electrode of the transistor, which will be described below, can mean the source or drain electrode. However, the terms “first electrode” and “second electrode” are just terms for distinguishing the electrodes. What corresponds to the electrode is not limited. In addition, for each electrode, the first electrode may not refer to the same electrode. For example, a first electrode of the first transistor T1 can mean a source electrode of the first transistor T1, and a first electrode of the sixth transistor T6 can mean a drain electrode of the sixth transistor T6.

In an embodiment, the driving transistor DT can be connected to the first transistor T1, which is connected to the first light-emitting element 140, and the second transistor T2 connected to the second light-emitting element 150. For example, a second electrode of the driving transistor DT can be connected to the first transistor T1 and the second transistor T2.

In an embodiment, the driving transistor DT can be connected to a first power line L17 configured to provide a high-potential power voltage ELVDD. For example, the first electrode of the driving transistor DT can be connected to the first power line L17. In case that the driving transistor DT is turned on, the high-potential power voltage ELVDD, which is supplied through the first power line L17, can be transmitted from the first electrode to the second electrode of the driving transistor DT.

In an embodiment, the first transistor T1 can be connected to at least one of the first light-emitting element 140, the second transistor T2, the fourth-first transistor T41, the fifth transistor T5, the seventh transistor T7, and the driving transistor DT.

Further, the first electrode of the first transistor T1 can be connected to at least one of the driving transistor DT, the second transistor T2, the fifth transistor T5, and the seventh transistor T7. The second electrode of the first transistor T1 can be connected to at least one of the fourth-first transistor T41 and the first light-emitting element 140. A gate electrode of the first transistor T1 can be connected to a first control line L10. The first transistor T1 can be turned on or off by a first control signal S(k) provided through the first control line L10. In case that the first transistor T1 is turned on, a voltage can be input to the first light-emitting element 140 (e.g., an anode electrode of the first light-emitting element 140) through the driving transistor DT and the seventh transistor T7.

In this situation, the first control signal S(k) can include a k-th first control signal supplied to a k-th column based on that the pixel circuit PC2 is disposed in the k-th column (k is a positive integer). The first control signal S(k) can be provided by the mode controller (or mode control circuit) and control an operation (or light emission) of the first light-emitting element 140 on which a first lens is disposed (e.g., a wide viewing angle lens).

In addition, the second transistor T2 can be connected to at least one of the second light-emitting element 150, the first transistor T1, the third transistor T3, the fourth-second transistor T42, the seventh transistor T7, and the driving transistor DT.

Also, a first electrode of the second transistor T2 can be connected to at least one of the driving transistor DT, the first transistor T1, the fifth transistor T5, and the seventh transistor T7. A second electrode of the second transistor T2 can be connected to at least one of the second light-emitting element 150 and the fourth-second transistor T42. A gate electrode of the second transistor T2 can be connected to a second control line L20. The second transistor T2 can be turned on or off by a second control signal P(k) provided through the second control line L20. In case that the second transistor T2 is turned on, a voltage can be input to the second light-emitting element 150 (e.g., an anode electrode of the second light-emitting element 150) through the driving transistor DT.

In an embodiment, the first light-emitting element 140 and the second light-emitting element 150 can each include a light-emitting diode. For example, the first light-emitting element 140 and the second light-emitting element 150 can each include an organic light-emitting diode.

In this situation, the second control signal P(k) can include a k-th second control signal supplied to the k-th column based on that the pixel circuit PC2 is disposed in the k-th column. The second control signal P(k) can be provided by the mode controller and control an operation (or light emission) of the second light-emitting element 150 on which a second lens is disposed.

In an embodiment, the first lens can be disposed on the first light-emitting element 140. A viewing angle of an area in which the first light-emitting element 140 is disposed can correspond to a first value by the first lens. For example, the viewing angle of the area in which the first light-emitting element 140 is disposed can be equal to the first value or more than the first value. The second lens can be disposed on the second light-emitting element 150. A viewing angle of an area in which the second light-emitting element 150 is disposed can correspond to a second value by the second lens. The second value can be smaller than the first value. For example, the viewing angle of the area in which the second light-emitting element 150 is disposed can be equal to the second value or less than the second value. For example, the first lens disposed on the first light-emitting element 140 can be a wide viewing angle lens for the sharing mode and the second lens disposed on the second light-emitting element 150 can be a narrow viewing angle lens for the privacy mode.

In an embodiment, assuming that the pixel circuit PC2 is disposed adjacent to a passenger seat, the area of the pixel circuit PC2, in which the first light-emitting element 140 is disposed, can have the viewing angle of the first value that allows light to be provided to a range corresponding to both the passenger seat and a driver seat adjacent to the passenger seat (e.g., a wide viewing angle). The area, in which the second light-emitting element 150 is disposed, can have the viewing angle of the second value that allows light to be provided to a range corresponding to the passenger seat (e.g., a narrow viewing angle). In this way, the passenger can view content having a narrow viewing angle in order to avoid distracting the driver, which can improve safety and convenience. Also, according to an embodiment, the display device 100 can be a standalone device (e.g., not included in a vehicle), which an selectively switch between the narrowing viewing angle mode and the wide viewing angle mode.

In addition, the third transistor T3 can be connected to at least one of the fourth-first transistor T41, the fourth-second transistor T42, the sixth transistor T6, and the capacitor Cst. For example, a first electrode of the third transistor T3 can be connected to the sixth transistor T6 and the capacitor Cst. A second electrode of the third transistor T3 can be connected to the fourth-first transistor T41 and the fourth-second transistor T42. A gate electrode of the third transistor T3 can be connected to a light-emitting signal line L15 configured to supply a light-emitting signal EM (n). The light-emitting signal EM (n) can correspond to an n-th light-emitting signal EM (n) supplied to an n-th row based on that the pixel circuit PC2 is disposed in the n-th pixel row (n is a positive integer). The third transistor T3 can be turned on or off by the light-emitting signal EM (n). The second electrode of the third transistor T3 can be connected to a reference voltage line L11, e.g., a second power line configured to supply a reference voltage Vref.

Further, the fourth-first transistor T41 can be connected to at least one of the first transistor T1, the third transistor T3, and the first light-emitting element 140. For example, a first electrode of the fourth-first transistor T41 can be connected to the third transistor T3. A second electrode of the fourth-first transistor T41 can be connected to the first transistor T1 and the first light-emitting element 140. A gate electrode of the fourth-first transistor T41 can be connected to an n-th second scan line L13. Therefore, the fourth-first transistor T41 can be supplied with an n-th second scan signal Scan2(n) and turned on or off by the n-th second scan signal Scan2(n).

In addition, the fourth-second transistor T42 can be connected to at least one of the second transistor T2, the third transistor T3, and the second light-emitting element 150. For example, a first electrode of the fourth-second transistor T42 can be connected to the third transistor T3. A second electrode of the fourth-second transistor T42 can be connected to the second transistor T2 and the second light-emitting element 150. A gate electrode of the fourth-second transistor T42 can be connected to the n-th second scan line L13. Therefore, the fourth-second transistor T42 can be supplied with the n-th second scan signal Scan2(n) and turned on or off by the n-th second scan signal Scan2(n).

Also, the fifth transistor T5 can be connected to at least one of the driving transistor DT, the fourth-first transistor T41, the fourth-second transistor T42, the capacitor Cst, the seventh transistor T7, the first transistor T1, and the second transistor T2. For example, a first electrode of the fifth transistor T5 can be connected to the driving transistor DT and the capacitor Cst. A second electrode of the fifth transistor T5 can be connected to the driving transistor DT, the seventh transistor T7, the first transistor T1, and the second transistor T2. A gate electrode of the fifth transistor T5 can be connected to the n-th second scan line L13 configured to supply a second scan signal Scan2(n) in the n-th row. The fifth transistor T5 can be supplied with the n-th second scan signal Scan2(n) and turned on or off by the n-th second scan signal Scan2(n).

According to an embodiment, an n-th first scan line L18 can provide an n-th first scan signal. In this situation, the n-th first scan signal can be provided to a gate electrode of the sixth transistor T6. The n-th second scan line L13 can provide an n-th second scan signal. In this situation, the n-th second scan signal can be provided to the gate electrode of each of the fourth-first transistor T41, the fourth-second transistor T42, and the fifth transistor T5.

In an embodiment, the sixth transistor T6 can be connected to at least one of the third transistor T3 and the capacitor Cst. For example, a first electrode of the sixth transistor T6 can be connected to the third transistor T3 and the capacitor Cst. A second electrode of the sixth transistor T6 can be connected to a data line L16 configured to supply a data voltage Vdata. A gate electrode of the sixth transistor T6 can be connected to the n-th first scan line L18 configured to supply an n-th first scan signal Scan1(n). The sixth transistor T6 can be supplied with the n-th first scan signal Scan1(n) and turned on or off by the n-th first scan signal Scan1(n). When the sixth transistor T6 is turned on, the data voltage Vdata can be transmitted from the second electrode to the first electrode.

The seventh transistor T7 can be connected to at least one of the first transistor T1, the second transistor T2, the fifth transistor T5, and the driving transistor DT. For example, a first electrode of the seventh transistor T7 can be connected to at least one of the fifth transistor T5 and the driving transistor DT. A second electrode of the seventh transistor T7 can be connected to at least one of the first transistor T1 and the second transistor T2.

In addition, a gate electrode of the seventh transistor T7 can be connected to a light-emitting signal line L30 configured to provide the light-emitting signal EM (n). The seventh transistor T7 can be turned on or off based on of the light-emitting signal EM (n). When the seventh transistor T7 is turned on, a voltage (or electric current) can be provided from the first electrode to the second electrode of the seventh transistor T7.

In an embodiment, the first light-emitting element 140 and/or the second light-emitting element 150 can be connected to a third power line L19, e.g., a third power line 435 in FIG. 4 that supplies a low-potential power voltage ELVSS. For example, a cathode electrode of the first light-emitting element 140 and a cathode electrode of the second light-emitting element 150 can be connected to the third power line L19 and supplied with the low-potential power voltage ELVSS.

Also, the low-potential power voltage can further include ground (or a ground voltage of 0 V (volt)). For example, the cathode electrode of the first light-emitting element 140 and the cathode electrode of the second light-emitting element 150 can be supplied with a voltage corresponding to the ground. However, embodiments of the present disclosure are not limited thereto.

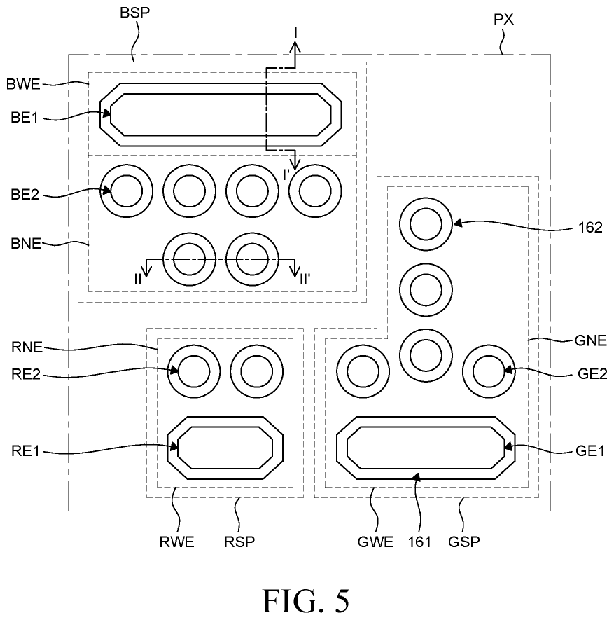

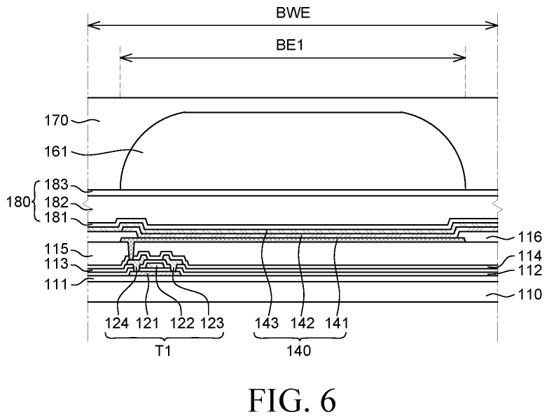

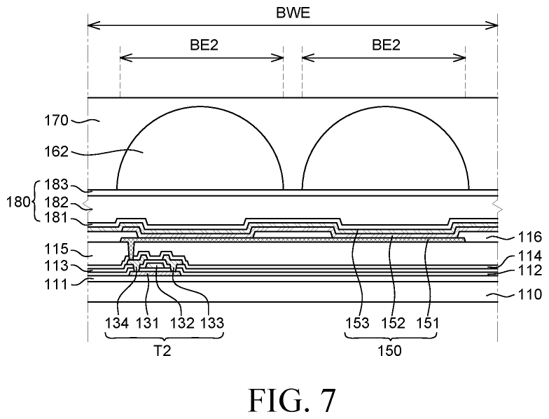

FIG. 5 is an enlarged top plan view illustrating the arrangement of the lenses included in the display device according to an embodiment of the present disclosure. FIG. 6 is a cross-sectional view taken along line I-I′ in FIG. 5. FIG. 7 is a cross-sectional view taken along line II-II′ in FIG. 5 according to an embodiment of the present disclosure. FIG. 5 illustrates a planar surface of the pixel PX in which three subpixels are disposed in the pixel PX according to an embodiment of the present disclosure. FIG. 6 illustrates a cross-section taken along line I-I′ in FIG. 5 according to an embodiment of the present disclosure, and FIG. 7 illustrates a cross-section taken along line II-II′ in FIG. 5 according to an embodiment of the present disclosure.

First, with reference to FIG. 5, the pixel PX can include a blue subpixel BSP configured to implement blue, a red subpixel RSP configured to implement red, and a green subpixel GSP configured to implement green. According to an embodiment, the blue subpixel BSP can correspond to a first subpixel, the red subpixel RSP can correspond to a second subpixel, and the green subpixel GSP can correspond to a third subpixel. The pixel circuit can correspond to each of the subpixels. The pixel circuit can be disposed to correspond to each of the subpixels.

The pixel PX can include first lens areas BWE, RWE, and GWE and second lens areas BNE, RNE, and GNE that provide different viewing angles. The second lens areas BNE, RNE, and GNE in each of the pixels PX can operate independently of the first lens areas BWE, RWE, and GWE in the corresponding pixel PX. For example, the pixels PX can each include the first light-emitting elements 140 (e.g., the first light-emitting elements 140 in FIG. 2) positioned in the first lens areas BWE, RWE, and GWE in the corresponding pixel PX, and the second light-emitting elements 150 (e.g., the second light-emitting elements 150 in FIG. 2) positioned in the second lens areas BNE, RNE, and GNE in the corresponding pixel PX. For example, a unit pixel can include three subpixels (e.g., red, green and blue), and each of those subpixels can have two light emitting elements, such as a light emitting element for providing a wide angle view and a light emitting element for providing a narrow angle view. Also, each of the six light emitting elements within the unit pixel can be controlled from the mode controller for activation. For example, two mode selection signals (e.g., S(k) and P(k)) can be used to selectively activate the six different light emitting elements, but embodiments are not limited thereto. According to another embodiment, one selection signal can be used to selectively activate the six different light emitting elements according to two different modes (e.g., a high level of the selection signal can active one mode, and a low level of the selection signal can activate the other viewing mode).

With reference to FIGS. 6 and 7 together, the display device 100 according to an embodiment of the present disclosure can include a substrate 110, a buffer film 111, a gate insulation film 112, an interlayer insulation film 113, a lower protective film 114, an overcoating layer 115, the first transistor T1, the second transistor T2, the first light-emitting element 140, the second light-emitting element 150, first lenses 161 (e.g., wide viewing angle lenses), second lenses 162 (e.g., narrow viewing angle lenses), a lens protective film 170, and an encapsulation member 180.

The substrate 110 can include an insulating material. The substrate 110 can include a transparent material. For example, the substrate 110 can include glass or plastic.

The first light-emitting element 140 can emit light with a particular color. For example, the first light-emitting element 140 can include a first lower electrode 141, a first light-emitting layer 142, and a first upper electrode 143 sequentially stacked on the substrate 110.

The first lower electrode 141 can include an electrically conductive material. The first lower electrode 141 can include a material having high reflectance. For example, the first lower electrode 141 can include metal such as aluminum (Al) and silver (Ag). The first lower electrode 141 can have a multilayer structure. For example, the first lower electrode 141 can have a structure in which a reflective electrode, which is made of metal, is positioned between transparent electrodes made of a transparent conductive material such as ITO and IZO.

The first light-emitting layer 142 can create light with brightness corresponding to a voltage difference between the first lower electrode 141 and the first upper electrode 143. For example, the first light-emitting layer 142 can include an emission material layer (EML) including a light-emitting material. The light-emitting material can include an organic material, an inorganic material, or a hybrid material.

The first light-emitting layer 142 can have a multilayer structure. For example, the first light-emitting layer 142 can further include at least one of a hole injection layer (HIL), a hole transport layer (HTL), an electron transport layer (ETL), and an electron injection layer (EIL).

The first upper electrode 143 can include an electrically conductive material. The first upper electrode 143 can include a material different than the material of the first lower electrode 141. A transmittance rate of the first upper electrode 143 can be higher than a transmittance rate of the first lower electrode 141. For example, the first upper electrode 143 can be configured as a transparent electrode made of a transparent conductive material such as ITO and IZO. Therefore, in the display device according to an embodiment of the present disclosure, the light created by the first light-emitting layer 142 can be discharged through the first upper electrode 143.

The second light-emitting element 150 can implement the same color as the first light-emitting element 140. The second light-emitting element 150 can have the same structure as the first light-emitting element 140. For example, the second light-emitting element 150 can include a second lower electrode 151, a second light-emitting layer 152, and a second upper electrode 153 sequentially stacked on the substrate 110.

The second lower electrode 151 can correspond to the first lower electrode 141, the second light-emitting layer 152 can correspond to the first light-emitting layer 142, and the second upper electrode 153 can correspond to the first upper electrode 143. For example, the second lower electrode 151 can be formed for the second light-emitting element 150 while having the same structure as the first lower electrode 141. The same can apply to the second light-emitting layer 152 and the second upper electrode 153. For example, the first light-emitting element 140 and the second light-emitting element 150 can be formed to have the same structure. However, embodiments of the present disclosure are not limited thereto. In some instances, the first light-emitting element 140 and the second light-emitting element 150 can be formed to be different from each other in at least some configurations.

In an embodiment, the second light-emitting layer 152 can be spaced apart from the first light-emitting layer 142. Therefore, in the display device according to an embodiment of the present disclosure, it is possible to suppress light emission caused by a leakage current.

According to an embodiment of the present disclosure, in the display device, only one of the first light-emitting layer 142 and the second light-emitting layer 152 can create light in accordance with the user's selection or a predesignated condition, but embodiments are not limited thereto. For example, according to another embodiment, both types of light emitting elements (e.g., both the narrow viewing angle light emitting element and the wide viewing angle light emitting element) can emit light at the same time according to a third mode (e.g., an increased brightness mode, or a lifespan extending mode in which current is divided across both types of light emitting elements).

In an embodiment, the buffer film 111, the gate insulation film 112, the interlayer insulation film 113, the lower protective film 114, and the overcoating layer 115 can be stacked on the substrate 110.

The buffer film 111 can include an insulating material. For example, the buffer film 111 can include an inorganic insulating material such as silicon oxide (SiOx) and silicon nitride (SiNx). The buffer film 111 can have a multilayer structure. For example, the buffer film 111 can have a stacked structure including a film made of silicon nitride (SiNx) and a film made of silicon oxide (SiOx).

In an embodiment, the buffer film 111 can be positioned between the substrate 110 and the drive part of each of the pixels PX. The buffer film 111 can suppress contamination caused by the substrate 110 during a process of forming the drive part. For example, a top surface of the substrate 110, which is directed toward the drive part of each of the pixels PX, can be covered by the buffer film 111. The drive part of each of the pixels PX can be positioned on the buffer film 111.

In addition, the gate insulation film 112 can include an insulating material. For example, the gate insulation film 112 can include an inorganic insulating material such as silicon oxide (SiO) and silicon nitride (SiN). The gate insulation film 112 can include a material having high permittivity. For example, the gate insulation film 112 can include a high-K material such as hafnium oxide (HfO). The gate insulation film 112 can have a multilayer structure.

The gate insulation film 112 can be positioned on the buffer film 111. The gate insulation film 112 can extend between the semiconductor layer and the gate electrode of the transistor. For example, the gate electrodes of the switching transistor ST and the driving transistor DT can be insulated from the semiconductor layers of the switching transistor ST and the driving transistor DT by the gate insulation film 112. The gate insulation film 112 can cover first and second semiconductor layers in each of the pixels PX. The gate electrodes of the switching transistor ST and the driving transistor DT can be positioned on the gate insulation film 112.

The interlayer insulation film 113 can include an insulating material. For example, the interlayer insulation film 113 can include an inorganic insulating material such as silicon oxide (SiO) and silicon nitride (SiN). The interlayer insulation film 113 can be positioned on the gate insulation film 112. The interlayer insulation film 113 can extend between the gate electrodes and the source electrodes and between the gate electrodes and the drain electrodes of the driving transistor DT and the switching transistor ST. For example, the source electrodes and the drain electrodes of the driving transistor DT and the switching transistor ST can be insulated from the gate electrodes by the interlayer insulation film 113. The interlayer insulation film 113 can cover the gate electrodes of the switching transistor ST and the driving transistor DT. The source electrode and the drain electrode in each of the pixels PX can be positioned on the interlayer insulation film 113. The gate insulation film 112 and the interlayer insulation film 113 can expose source and drain areas of each semiconductor pattern positioned in each of the pixels PX.

Also, the lower protective film 114 can include an insulating material. For example, the lower protective film 114 can include an inorganic insulating material such as silicon oxide (SiO) and silicon nitride (SiN). The lower protective film 114 can be positioned on the interlayer insulation film 113. The lower protective film 114 can suppress damage to the drive part caused by external moisture and impact. The lower protective film 114 can extend along a surface of the driving transistor DT and a surface of the switching transistor ST that are opposite to the substrate 110. The lower protective film 114 can be in contact with the interlayer insulation film 113 outside the drive part positioned in each of the pixels PX.

The overcoating layer 115 can include an insulating material. The overcoating layer 115 can include a material different from the material of the lower protective film 114. For example, the overcoating layer 115 can include an organic insulating material. The overcoating layer 115 can be positioned on the lower protective film 114. The overcoating layer 115 can remove a level difference caused by the drive part in each of the pixels PX. For example, a top surface of the overcoating layer 115, which is opposite to the element substrate 110, can be a flat surface. For example, the overcoating layer 115 can be a planarization layer.

In an embodiment, the first transistor T1 can be electrically connected between the drain electrode of the driving transistor DT and the first lower electrode 141 of the first light-emitting element 140. The second transistor T2 can be electrically connected between the drain electrode of the driving transistor DT and the second lower electrode 151 of the second light-emitting element 150.

The first transistor T1 can include a first semiconductor layer 121, a first gate electrode 122, a first source electrode 123, and a first drain electrode 124. The first transistor T1 can have the same structure as the switching transistor ST and the driving transistor DT. For example, the first semiconductor layer 121 can be positioned between the buffer film 111 and the gate insulation film 112, and the first gate electrode 122 can be positioned between the gate insulation film 112 and the interlayer insulation film 113. The first source electrode 123 and the first drain electrode 124 can be positioned between the interlayer insulation film 113 and the lower protective film 114. The first gate electrode 122 can overlap a channel area of the first semiconductor layer 121. The first source electrode 123 can be electrically connected to a source area of the first semiconductor layer 121. The first drain electrode 124 can be electrically connected to a drain area of the first semiconductor layer 121.

In addition, the second transistor T2 can include a second semiconductor layer 131, a second gate electrode 132, a second source electrode 133, and a second drain electrode 134. For example, the second semiconductor layer 131 can be positioned on the same layer as the first semiconductor layer 121, the second gate electrode 132 can be positioned on the same layer as the first gate electrode 122, and the second source electrode 133 and the second drain electrode 134 can be positioned on the same layer as the first source electrode 123 and the first drain electrode 124.

Also, the first transistor T1 can be formed simultaneously with the switching transistor ST and the driving transistor DT. The first transistor T1 can be formed simultaneously with the second transistor T2.

The first light-emitting element 140 and the second light-emitting element 150 in each of the pixels PX can be positioned on the overcoating layer 115 in the corresponding pixel PX. For example, the first lower electrode 141 of the first light-emitting element 140 can be electrically connected to the first drain electrode 124 (or the first source electrode 123) of the first transistor T1 through contact holes formed through the lower protective film 114 and the overcoating layer 115, and the second lower electrode 151 of the second light-emitting element 150 can be electrically connected to the second drain electrode 134 (or the second source electrode 133) of the second transistor T2 through contact holes formed through the lower protective film 114 and the overcoating layer 115.

The second lower electrode 151 in each of the pixels PX can be spaced apart from the first lower electrode 141 in the corresponding pixel PX. For example, a bank insulation film 116 can be positioned between the first lower electrode 141 and the second lower electrode 151 in each of the pixels PX. The bank insulation film 116 can include an insulating material. For example, the bank insulation film 116 can include an organic insulating material. The bank insulation film 116 can include a material different from the material of the overcoating layer 115.

The second lower electrode 151 in each of the pixels PX can be insulated from the first lower electrode 141 in the corresponding pixel PX by the bank insulation film 116. For example, the bank insulation film 160 can cover an edge of the first lower electrode 141 and an edge of the second lower electrode 151 positioned in each of the pixels PX. Therefore, the display device can provide the user with images made by the first lens areas BWE, RWE, and GWE in each of the pixels PX in which the first light-emitting element 140 is positioned or images made by the second lens areas BNE, RNE, and GNE in each of the pixels PX in which the second light-emitting element 150 is positioned.

The first light-emitting layer 142 and the first upper electrode 143 of the first light-emitting element 140, which is positioned in each of the pixels PX, can be stacked in a partial area of the corresponding first lower electrode 141 exposed by the bank insulation film 116. The second light-emitting layer 152 and the second upper electrode 153 of the second light-emitting element 150, which is positioned in each of the pixels PX, can be stacked in a partial area of the corresponding second lower electrode 151 exposed by the bank insulation film 116. For example, in each of the pixels PX, the bank insulation film 116 can be divided into first light-emitting areas BE1, RE1, and GE1 in which light is emitted by the first light-emitting element 140, and second light-emitting areas BE2, RE2, and GE2 in which light is emitted by the second light-emitting element 150. In each of the pixels PX, a size of each of the second light-emitting areas BE2, RE2, and GE2 can be smaller than a size of each of the first light-emitting areas BE1, RE1, and GE1.

In each of the pixels PX, the second upper electrode 153 can be electrically connected to the first upper electrode 143 in the corresponding pixel PX. For example, a voltage, which is applied to the second upper electrode 153 of the second light-emitting element 150 positioned in each of the pixels PX, can be equal to a voltage applied to the first upper electrode 143 of the first light-emitting element 140 positioned in the corresponding pixel PX. The second upper electrode 153 in each of the pixels PX can include the same material as the first upper electrode 143 in the corresponding pixel PX. For example, the second upper electrode 153 in each of the pixels PX can be formed simultaneously with the first upper electrode 143 in the corresponding pixel PX. The second upper electrode 153 in each of the pixels PX can extend on the bank insulation film 116 and be in direct contact with the first upper electrode 143 in the corresponding pixel PX. The brightness in the first lens areas BWE, RWE, and GWE positioned in each of the pixels PX and the brightness in the second lens areas BNE, RNE, and GNE can be controlled by a drive current generated in the corresponding pixel PX.

The encapsulation member 180 can be positioned on the first light-emitting element 140 and the second light-emitting element 150 in each of the pixels PX. The encapsulation member 180 can suppress damage to the light-emitting elements 140 and 150 caused by moisture and impact from the outside. The encapsulation member 180 can have a multilayer structure. For example, the encapsulation member 180 can include a first encapsulation layer 181, a second encapsulation layer 182, and a third encapsulation layer 183 sequentially stacked. However, the embodiments of the present specification are not limited thereto. The first encapsulation layer 181, the second encapsulation layer 182, and the third encapsulation layer 183 can include an insulating material. The second encapsulation layer 182 can include a material different from the material of the first encapsulation layer 181 and the third encapsulation layer 183. For example, the first encapsulation layer 181 and the third encapsulation layer 183 are inorganic encapsulation layers including an inorganic insulating material, and the second encapsulation layer 182 can include an organic encapsulation layer including an organic insulating material. Therefore, damage to the light-emitting elements 140 and 150 of the display device caused by moisture and impact from the outside can be more effectively suppressed.

The first lenses 161 and the second lenses 162 can be positioned on the encapsulation member 180 in each of the pixels PX.

The first lenses 161 can be positioned on the first lens areas BWE, RWE, and GWE in each of the pixels PX. For example, the light, which is created by the first light-emitting element 140 in each of the pixels PX, can be discharged through the first lens 161 in the corresponding pixel PX. The first lens 161 can have a shape in which at least light in one direction may not be restricted. For example, a planar shape of the first lens 161 positioned in each of the pixels PX can be a bar shape extending in a first direction. For example, the first lens 161 can have a semi-cylindrical shape or a rounded rectangle shape in a plan view.

In this situation, the propagation direction of the light emitted from the first lens areas BWE, RWE, and GWE in the pixel PX is not limited to the first direction. For example, the content (or images) provided through the first lens areas BWE, RWE, and GWE in the pixel PX can be shared with surrounding people adjacent to the user in the first direction (e.g., a sharing mode with a wide viewing angle). The situation in which the content is provided through the first lens areas BWE, RWE, and GWE is a mode in which the content is provided within a first viewing angle range larger than a second viewing angle range in which the second lens areas BNE, RNE, and GNE are provided, and this mode can be referred to as a first mode (e.g., a sharing mode with a wide viewing angle).

The second lenses 162 can be positioned on the second lens areas BNE, RNE, and GNE in each of the pixels PX. The light, which is created by the second light-emitting element 150 in the pixel PX, can be discharged through the second lens 162 in the corresponding pixel PX. The second lens 162 can restrict the propagation direction, in which light passes through the second lens 520, to the first direction and/or a second direction. For example, a planar shape of the second lens 162 positioned in the pixel PX can be a circular shape (e.g., the second lens 162 can have a hemispherical shape or a dome shape). In this situation, the propagation direction of the light emitted from the second lens areas BNE, RNE, and GNE in the pixel PX can be restricted to the first and second directions. For example, the content provided by the second lens areas BNE, RNE, and GNE in the pixel PX may not be shared with surrounding people adjacent to the user. The situation in which the content is provided through the second lens areas BNE, RNE, and GNE is a mode in which the content is provided within the second viewing angle range smaller than the first viewing angle range in which the first lens areas BWE, RWE, and GWE are provided, and this mode can be referred to as a second mode (e.g., a privacy mode with a narrow viewing angle).

The first light-emitting areas BE1, RE1, and GE1 included in the first lens areas BWE, RWE, and GWE in each of the pixels PX can have shapes corresponding to the first lenses 161 positioned in the first lens areas BWE, RWE, and GWE in the corresponding pixel PX. For example, planar shapes of the first light-emitting areas BE1, RE1, and GE1 defined in the first lens areas BWE, RWE, and GWE in each of the pixels PX can each be a bar shape extending in the first direction. The first lenses 161 positioned in the first lens areas BWE, RWE, and GWE in the pixel PX can have sizes larger than those of the first light-emitting areas BE1, RE1, and GE1 included in the first lens areas BWE, RWE, and GWE in the corresponding pixel PX. Therefore, it is possible to improve the efficiency of the light emitted from the first light-emitting areas BE1, RE1, and GE1 in the pixel PX.

The second light-emitting areas BE2, RE2, and GE2 included in the second lens areas BNE, RNE, and GNE in each of the pixels PX can have shapes corresponding to the second lenses 162 positioned in the second lens areas BNE, RNE, and GNE in the corresponding pixel PX. For example, planar shapes of the second light-emitting areas BE2, RE2, and GE2 included in the second lens areas BNE, RNE, and GNE in the pixel PX can each be a circular shape. The second lenses 162 positioned in the second lens areas BNE, RNE, and GNE in the pixel PX can have sizes larger than those of the second light-emitting areas BE2, RE2, and GE2 included in the second lens areas BNE, RNE, and GNE in the corresponding pixel PX. For example, planar shapes of the second light-emitting areas BE2, RE2, and GE2 positioned in the second lens areas BNE, RNE, and GNE in each of the pixels PX can be circular shapes concentric to planar shapes of the second lenses 162 positioned in the second lens areas BNE, RNE, and GNE in the corresponding pixel PX. In this situation, it is possible to improve the efficiency of the light emitted from the second light-emitting areas BE2, RE2, and GE2 in the pixel PX.

In an embodiment, the first lens area BWE, RWE, or GWE in the pixel PX can include one first light-emitting area BE1, RE1, or GE1. The second lens areas BNE, RNE, and GNE in the pixel PX can include the plurality of second light-emitting areas BE2, RE2, and GE2.

In addition, one first lens 161 can be disposed in the first lens area BWE, RWE, or GWE in the pixel PX. A plurality of second lenses 162 can be disposed in the second lens areas BNE, RNE, and GNE in the pixel PX.

In an embodiment, the second light-emitting areas BE2, RE2, and GE2 included in the second lens areas BNE, RNE, and GNE in the pixel PX can operate for the respective subpixels. The second light-emitting areas (e.g., the second light-emitting areas BE2, the second light-emitting areas RE2, or the second light-emitting areas GE2) included in one subpixel can operate simultaneously.

In an embodiment, one second lower electrode 151 can be positioned in the second lens area BNE, RNE, or GNE in each of the pixels PX. The bank insulation film 116 between the second light-emitting areas BE2, RE2, and GE2 can be positioned between the second lower electrode 151 and the second light-emitting layer 152. The bank insulation film 116, which is disposed between the second light-emitting areas BE2, between the second light-emitting areas RE2, and/or between the second light-emitting areas GE2, can be positioned between the second lower electrode 151 and the second light-emitting layer 152. The second light-emitting layer 152, which is disposed between the second light-emitting areas BE2, RE2, and GE2 in the second lens areas BNE, RNE, and GNE, can be spaced apart from the second lower electrode 151 by the bank insulation film 116. In this situation, it is possible to improve the luminous efficiency of the second light-emitting areas BE2, RE2, and GE2.

In an embodiment, areas of the second light-emitting areas BE2, RE2, and GE2 positioned in the second lens areas BNE, RNE, and GNE in the pixel PX can be designated as particular values. For example, the areas of the second light-emitting areas BE2, RE2, and GE2 positioned in the second lens areas BNE, RNE, and GNE can be implemented to be equal to one another. The area of each of the second light-emitting areas BE2, RE2, and GE2 positioned in the second lens areas BNE, RNE, and GNE in the pixel PX can be equal to the area of each of the second light-emitting areas BE2, RE2, and GE2 included in the second lens areas BNE, RNE, and GNE in the adjacent pixel PX.

In addition, the number of second light-emitting areas can vary depending on the subpixels RSP, GSP, and BSP. For example, the number of second light-emitting areas BE2 defined in the second lens area BNE in the blue subpixel BSP can be larger than the number of second light-emitting areas RE2 defined in the second lens area RNE in the red subpixel RSP. The number of second light-emitting areas RE2 defined in the second lens area RNE in the red subpixel RSP can be larger than the number of second light-emitting areas GE2 defined in the second lens area GNE in the green subpixel GSP. In this situation, an efficiency deviation between the second light-emitting elements 150 positioned in the second lens areas BNE, RNE, and GNE in the pixel PX can be compensated for by the number of second light-emitting areas BE2, RE2, and GE2 defined in the second lens areas BNE, RNE, and GNE in each of the pixels PX.

In an embodiment, the sizes of the first light-emitting areas BE1, RE1, and GE1 can be different from one another for the respective subpixels RSP, GSP, and BSP. For example, the first light-emitting area BE1 in the blue subpixel BSP can have a different size than the first light-emitting area RE1 in the red subpixel RSP and can have a different size from first light-emitting area GE1 in the green subpixel GSP. The size of the first light-emitting area BE1 in the blue subpixel BSP can be larger than the size of the first light-emitting area RE1 in the red subpixel RSP. The size of the first light-emitting area RE1 in the red subpixel RSP can be larger than the size of the first light-emitting area GE1 in the green subpixel GSP. Therefore, in the display device according to an embodiment of the present disclosure, an efficiency deviation between the first light-emitting elements 140 positioned in the first lens areas BWE, RWE, and GWE in each of the pixels PX can be compensated for by the sizes of the first light-emitting areas BE1, RE1, and GE1 defined in the first lens areas BWE, RWE, and GWE in each of the pixels PX.

In an embodiment, the lens protective film 160 can be positioned on the first lens 161 and the second lens 162 in the pixel PX. The lens protective film 160 can include an insulating material. For example, the lens protective film 160 can include an organic insulating material. A refractive index of the lens protective film 160 can be smaller than a refractive index of the first lens 161 and a refractive index of the second lens 162 positioned in each of the pixels PX. Therefore, in the display device 100 according to an embodiment of the present disclosure, the light, which has passed through the first lens 161 and the second lens 162 in each of the pixels PX, may not be reflected toward the substrate 110 because of a difference from the refractive index of the lens protective film 160.

FIG. 8 is a schematic top plan view of the display device according to an embodiment of the present disclosure.

With reference to FIG. 8, the display device 100 can include the substrate 110, a printed circuit board PCB, a flexible film CF, the mode controller MC, a first level shift LS1 (e.g., a first level shifter), a second level shift LS2 (e.g., a second level shifter), mux parts MUX, and pixel blocks PB.

The flexible film CF is disposed at one end of the substrate 110. The flexible film CF is a film having various types of components disposed on a base film having flexibility in order to supply signals to the plurality of pixels in the display area. Meanwhile, FIG. 8 illustrates a single flexible film CF. However, a plurality of flexible films CF can be disposed. In this situation, the number of flexible films CF can be variously changed in accordance with design. However, the present disclosure is not limited thereto.

The printed circuit board PCB is connected to the flexible film CF. The printed circuit board PCB is a component for supplying a signal to the drive IC. Various types of components for supplying the drive IC with various driving signals such as driving signals, data voltages, and the like can be disposed on the printed circuit board PCB. Meanwhile, FIG. 8 illustrates a single printed circuit board PCB. However, the number of printed circuit boards PCB can be variously changed in accordance with design. The present disclosure is not limited thereto.

With reference to FIG. 8, the plurality of pixel blocks PB is disposed on the substrate 110. For example, the pixel block PB can refer to units of the plurality of pixels PX to which the same mode signal is transmitted. That is, the pixel blocks PB can each include the plurality of pixels PX to which the same mode signal is transmitted. Meanwhile, FIG. 8 illustrates a total of sixteen pixel blocks PX are disposed in four rows and four columns on the substrate 110. However, the number and arrangement of the pixel blocks PX can be changed in accordance with design of the display device 100. However, embodiments of the present disclosure are not limited thereto.

The pixel block PB can operate in a first mode PBS (e.g., pixel block sharing viewing mode) or a second mode PBP (e.g., pixel block privacy viewing mode). The first mode PBS can refer to an operating mode of the pixel block PB in which the viewing angle has the first value (e.g., wide viewing angle). The second mode PBP can refer to an operating mode of the pixel block PB in which the viewing angle has the second value smaller than the first value (e.g., narrow viewing angle). When the pixel block PB operates in the second mode PBP, a visual field in which the content is displayed, can be limited to a particular range. Further, when the pixel block PB operates in the first mode PBS, the user can visually recognize the content displayed on the pixel block PB within a range larger than a range in which the pixel block PB operates in the second mode PBP.

For example, in an embodiment, the display device 100 can be disposed in the vehicle. In this situation, depending on the user's needs, it can be necessary to operate the pixel block PB of the display device 100, which is disposed adjacent to the driver seat, and the pixel block PB, which is disposed adjacent to the passenger seat, in different modes. Therefore, the pixel block PB, which is disposed adjacent to the driver seat, can be configured such that the content displayed by the operation in the first mode (e.g., share viewing mode having a wide viewing angle) can be visually recognized from both the driver seat and the passenger seat. The pixel block PB, which is disposed adjacent to the passenger seat, can be configured such that the content displayed by the operation in the second mode (e.g., privacy viewing mode having a narrow viewing angle) can be visually recognized from a portion excluding the driver seat, e.g., visually recognized only from the passenger seat. In this way, a passenger seated next to the driver can comfortably watch or view content while in the second mode (e.g., privacy viewing mode) without disturbing the driver, since it can display content with a narrow viewing angle.

The plurality of mux parts MUX (e.g., multiplexers) are disposed on the substrate 110 and corresponds to the columns of the plurality of pixel blocks PB. The mux part MUX can be disposed to correspond to the column of each of the plurality of pixel blocks PB. The mux parts MUX can transmit mode signals to the plurality of pixel blocks PB in response to a control signal received from the mode controller MC. For example, when the plurality of pixel blocks PB are disposed in m rows and n columns, the number of mux parts MUX can be n (here, n and m are positive integers). That is, the mux parts MUX can include first to n-th mux parts MUX1 to MUXn. For example, the plurality of mux parts MUX can include first to fourth mux parts MUX1 to MUX4. Meanwhile, FIG. 8 illustrates that four mux parts MUX are disposed in the display device 100. However, the number of mux parts MUX can be changed in accordance with design of the display device 100. However, embodiments of the present disclosure are not limited thereto.

The plurality of mux parts MUX can each include a plurality of switching elements SE. The plurality of switching elements SE can be respectively connected to the rows on one column of the plurality of pixel blocks PB. The mux part MUX can turn on or off the plurality of switching elements SE and transmit the first mode signal or second mode signal to the pixel block PB. For example, the plurality of switching elements SE can each be an n-type transistor or a p-type transistor. However, embodiments of the present disclosure are not limited thereto.

For example, in the situation that the plurality of switching elements SE are the p-type transistors, in the p-type transistor, a low-level voltage of each of the driving signals can mean a voltage that turns on the TFT, and a high-level voltage of each of the driving signals can mean a voltage that turns off the TFTs.

The plurality of switching elements SE include a first switching element SE1 configured to transmit the first mode signal to the pixel block PB, and a second switching element SE2 configured to transmit the second mode signal to the pixel block PB. That is, the first switching element SE1 can be connected to the pixel block PB and turned on to transmit the first mode signal to the pixel block PB. The second switching element SE2 can be connected to the pixel block PB and turned on to transmit the second mode signal to the pixel block PB.

In each of the pixel blocks PB, one first switching element SE1 and one second switching element SE2 are disposed to correspond to each other. That is, in the situation that the plurality of pixel blocks PB are disposed in m rows and n columns, the number of first switching elements SE1 can be m×n, and the number of second switching elements SE2 can be m×n (here, n and m are positive integers). For example, as illustrated in FIG. 8, when the plurality of pixel blocks is disposed in four rows and four columns, the number of first switching elements can be sixteen, and the number of second switching elements can be sixteen. For example, four first switching elements SE1 and four second switching elements SE2 can be disposed on a first mux part MUX1, four first switching elements SE1 and four second switching elements SE2 can be disposed on a second mux part MUX2, four first switching elements SE1 and four second switching elements SE2 can be disposed on a third mux part MUX3, and four first switching elements SE1 and four second switching elements SE2 can be disposed on a fourth mux part MUX4. Meanwhile, FIG. 8 illustrates that sixteen first switching elements SE1 and sixteen second switching elements SE2 are disposed in the display device 100. However, the number of first switching elements SE1 and the number of second switching elements SE2 can be changed in accordance with design of the display device 100. However, embodiments of the present disclosure are not limited thereto.

Meanwhile, the mux part MUX can be configured to selectively turn on only one switching element SE among the first and second switching elements SE1 and SE2 corresponding to one pixel block PB. Therefore, one pixel block PB can operate in any one mode selected from the first and second modes. For example, the display device can selectively operate in either the first mode or the second mode on a pixel block-by-pixel block basis.

The first and second switching elements SE1 and SE2, which correspond to one pixel block PB, can be respectively connected to a plurality of mode signal lines MSL. The plurality of mode signal lines MSL include a first mode signal line MSL1 configured to transmit the first mode signal to the pixel block PB, and a second mode signal line MSL2 configured to transmit the second mode signal to the pixel block PB. That is, the first mode signal line MSL1 can connect the first switching element SE1 and the pixel block PB, and the second mode signal line MSL2 can connect the second switching element SE2 and the pixel block PB.

The mode controller MC, the first level shift LS1, and the second level shift LS2 are disposed on the printed circuit board PCB.

The mode controller MC can provide the plurality of pixel blocks PB with signals for controlling the modes of the plurality of pixel blocks PB. For example, the mode controller MC can control the first level shift LS1 and the second level shift LS2 and provide the first mode signal for controlling the first mode of the plurality of pixel blocks PB and the second mode signal for controlling the second mode. The mode controller MC can be defined as a component included in the timing controller T-con or defined as a component provided separately from the timing controller T-con.

The first level shift LS1 can transmit the first mode signal or second mode signal, which is related to mode of the plurality of pixel blocks PB, to the plurality of mux parts MUX. For example, the first level shift LS1 can be implemented for each of the first and second mode signals to be provided to the plurality of pixel blocks PB. However, the first level shift LS1 can be implemented as a single component by changing a range of an output voltage of the first and second mode signals according to the embodiment. However, embodiments of the present disclosure are not limited thereto.

A plurality of first mode signal link lines LL1 and a plurality of second mode signal link lines LL2 are disposed to connect the first level shift LS1 and the plurality of switching elements SE. Specifically, the first mode signal link line LL1 is disposed to connect the first level shift LS1 and the first switching element SE1, and the second mode signal link line LL2 is disposed to connect the first level shift LS1 and the second switching element SE2.

For example, the plurality of first mode signal link lines LL1, which are disposed in the same column among the plurality of first mode signal link lines LL1, can transmit the same first mode signal to the plurality of pixel blocks PB disposed in the same column. For example, the plurality of second mode signal link lines LL2, which are disposed in the same column among the plurality of second mode signal link lines LL2, can transmit the same second mode signal to the plurality of pixel blocks PB disposed in the same column. Therefore, as illustrated in FIG. 8, the plurality of first mode signal link lines LL1, which are disposed in the same column, and the plurality of second mode signal link lines LL2, which are disposed in the same column, can be disposed by branching off from one line connected to the first level shift LS1. However, embodiments of the present disclosure are not limited thereto.

The plurality of first mode signal link lines LL1 and the plurality of second mode signal link lines LL2 can connect the first level shift LS1 and the plurality of mux parts MUX. For example, the plurality of first mode signal link lines LL1 and the plurality of second mode signal link lines LL2 can be connected to the plurality of mux parts MUX. For example, the first mode signal link line LL1 can include a first-first mode signal link line LL1-1 connected to the first mux part MUX1, a first-second mode signal link line LL1-2 connected to the second mux part MUX2, a first-third mode signal link line LL1-3 connected to the third mux part MUX3, and a first-fourth mode signal link line LL1-4 connected to the fourth mux part MUX4, and the second mode signal link line LL2 can include a second-first mode signal link line LL2-1 connected to the first mux part MUX1, a second-second mode signal link line LL2-2 connected to the second mux part MUX2, a second-third mode signal link line LL2-3 connected to the third mux part MUX3, and a second-fourth mode signal link line LL2-4 connected to the fourth mux part MUX4. Meanwhile, FIG. 8 illustrates that four first mode signal link lines LL1 and four second mode signal link lines LL2 are disposed in the display device 100. However, the number of first mode signal link lines LL1 and the number of second mode signal link lines LL2 can be changed in accordance with design of the display device 100. However, embodiments of the present disclosure are not limited thereto.

The second level shift LS2 transmits a plurality of mux signals to the plurality of mux parts MUX. The second level shift LS2 can time-divide the signal, which is received from the mode controller MC, and transmit the plurality of mux signals to the plurality of mux parts MUX. Meanwhile, FIG. 8 illustrates that two second level shifts LS2 are disposed at two opposite sides of the printed circuit board PCB. However, only a single second level shift LS2 can be disposed. However, embodiments of the present disclosure are not limited thereto.

A plurality of mux signal lines ML are disposed to connect the second level shift LS2 and the plurality of switching elements SE. Therefore, the plurality of mux signals, which are time-divided by the second level shift LS2, can be transmitted to the plurality of mux parts MUX through the plurality of mux signal lines ML.

The plurality of mux signal lines ML can be disposed to correspond to the number of rows of the plurality of pixel blocks PB. For example, when the plurality of pixel blocks PB is disposed in m rows and n columns, the number of mux signal lines ML can be m (here, n and m are positive integers). That is, the plurality of mux signal lines ML can include first to m-th mux signal lines ML1 to MLm. For example, as illustrated in FIG. 8, when the plurality of pixel blocks are disposed in four rows, the plurality of mux signal lines ML can include first to fourth mux signal lines ML1 to ML4. Meanwhile, FIG. 8 illustrates that four mux signal lines ML are disposed in the display device 100. However, the number of mux signal lines ML can be changed in accordance with design of the display device 100. However, embodiments of the present disclosure are not limited thereto.

For example, a gate electrode of the switching element SE can be connected to the second level shift LS2 through the mux signal line ML, a first electrode of the switching element SE can be connected to the first level shift LS1 through the first mode signal link line LL1 or the second mode signal link line LL2, and a second electrode of the switching element SE can be connected to the pixel block PB through the mode signal line MSL.

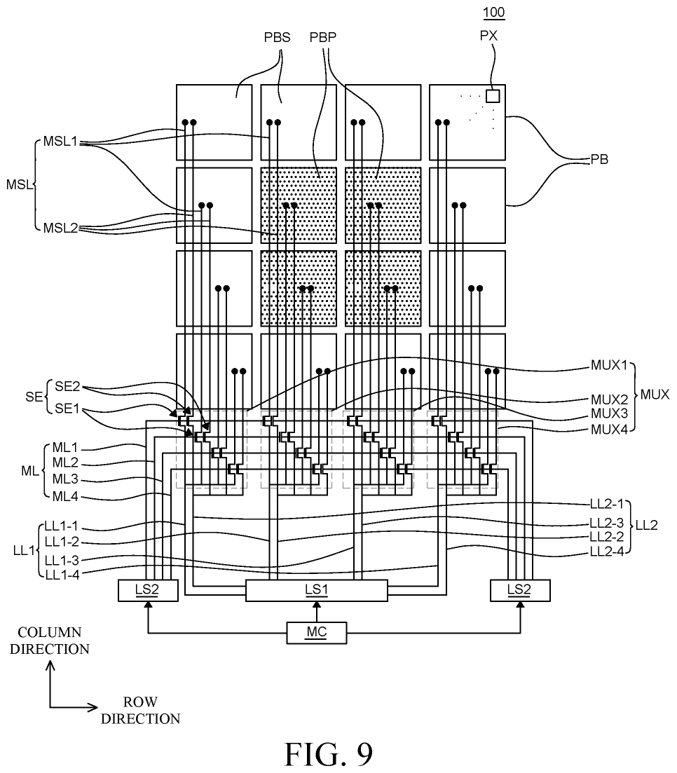

Hereinafter, operational examples of the display device according to embodiments of the present disclosure will be described in detail with reference to FIGS. 9 to 12.

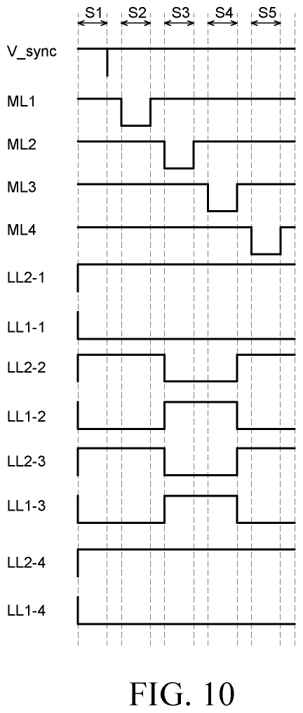

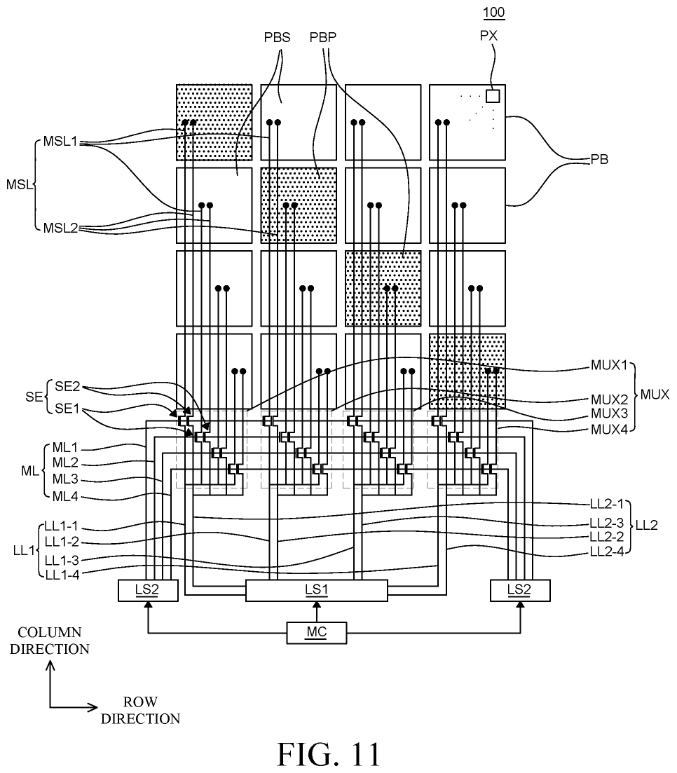

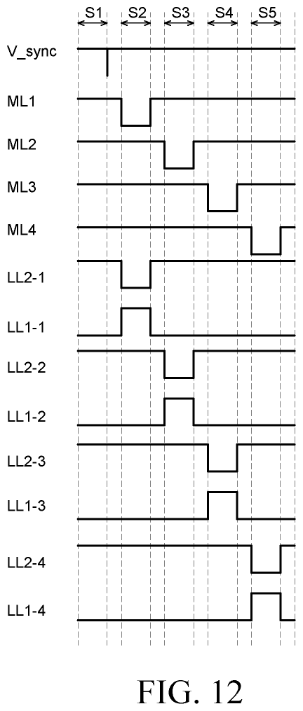

FIG. 9 is a schematic top plan view of the display device illustrating one operation example of the display device according to an embodiment of the present disclosure. FIG. 10 is a timing diagram for explaining an operational example of the display device according to an embodiment of the present disclosure. FIG. 11 is a top plan view illustrating another operational example of the display device according to the embodiment of the present disclosure. FIG. 12 is a timing diagram for explaining still another operational example of the display device according to an embodiment of the present disclosure. For convenience of description, FIGS. 9 and 11 illustrate only the plurality of pixel blocks PB, the mode controller MC, the first level shift LS1, the second level shift LS2, and the plurality of mux parts MUX. In this situation, in FIGS. 9 and 11, the non-hatched pixel block PB indicates a pixel block PBS that operates in the first mode (e.g., wide viewing angle mode or sharing view mode), and the hatched pixel block PB indicates a pixel block PBP that operates in the second mode (e.g., narrow viewing angle mode or privacy view mode).

With reference to FIGS. 9 and 11, the plurality of pixel blocks PB can operate in the first mode signal or second mode. For example, the first mode can refer to an operating mode of the pixel block PBS in which the viewing angle has the first value (e.g., wide viewing angle). The second mode can refer to an operating mode of the pixel block PBP in which the viewing angle has the second value (e.g., narrowing viewing angle) smaller than the first value. When the pixel block PB operates in the second mode, a visual field in which the content is displayed, can be limited to a particular range. Further, when the pixel block PB operates in the first mode, the user can visually recognize the content displayed on the pixel block PB within a range that is larger than a range in which the pixel block PB operates in the second mode.

In the display device 100 according to an embodiment of the present disclosure, among the plurality of pixel blocks PB, some of the pixel blocks PBS can operate in the first mode, and the remaining pixel blocks PBP can operate in the second mode. For example, the display device can selectively operate in either the first mode or the second mode on a pixel block-by-pixel block basis.

For example, each of the pixel-blocks can be selectively driven in the first mode (e.g., share viewing mode) or the second mode (e.g., privacy viewing mode) by the mode controller MC. Therefore, within the display area, only a localized area in which images or private contents requiring privacy protection are displayed can be displayed at the narrow viewing angle. For example, in this way, a driver and a passenger can both share and view wide viewing angle content on a same screen, but a small portion of the screen can be activated within the second mode (e.g., privacy viewing mode) in an area of the screen that is in front of the passenger to provide sensitive information with a narrow viewing angle, such as personal notifications, or to provide information that is only relevant to the passenger in order to not distract the driver, but embodiments are not limited thereto. For example, the screen can be any type of display device, such as a TV, monitor, smart phone, tablet, etc.

In this way, a user can be viewing their display device while in public in which most content is displayed in the first mode (e.g., share viewing mode) with a wide viewing angle, but the user can select certain types of sensitive information to only be displayed on a small portion or selective portion of the screen according to the second mode (e.g., privacy viewing mode) with a narrow viewing angle, such as personal messages or other notifications, etc. In this way, a user can privately view sensitive information while preventing other nearby people from seeing such information (e.g., coworkers, strangers, etc.).

Also, since each individual pixel block can be selectively controlled to operate in the first mode (e.g., share viewing mode) and the second mode (e.g., privacy viewing mode) on a pixel block by pixel block basis, a user can have the freedom to selectively designate any specific area on the screen as a type of “secret” display area or “special” display area for displaying sensitive information in a narrow viewing angle mode, while the rest of the screen can operate in a wide viewing angle mode that can be viewed by both the driver and the passenger.

In addition, according to an embodiment, a shared screen can be used by two or more video game players and different portions of the screen can be operated in the first mode (e.g., share viewing mode) or the second mode the second mode (e.g., privacy viewing mode) so that some content can be seen by all players while also providing specific content to individual players, etc.

For example, as illustrated in FIG. 9, among the sixteen pixel blocks PB in the display device 100, four pixel blocks PBP at a central portion can operate in the second mode (e.g., privacy viewing mode), and the remaining pixel blocks PBS can operate in the first mode (e.g., share viewing mode).

With reference to FIG. 10 together, the mode controller MC generates a synchronizing signal V_sync that can separate a plurality of periods S1 to S5. The synchronizing signal V_sync can be generated once for one frame.

First, during a first period S1, in response to the mode signal received from the mode controller MC, the first level shift LS1 transmits low-level signals to the first-first mode signal link line LL1-1, the first-second mode signal link line LL1-2, the first-third mode signal link line LL1-3, and the first-fourth mode signal link line LL1-4 and transmits high-level signals to the second-first mode signal link line LL2-1, the second-second mode signal link line LL2-2, the second-third mode signal link line LL2-3, and the second-fourth mode signal link line LL2-4. However, during the first period S1, because the mux signals are not transmitted from the second level shift LS2 to the plurality of mux signal lines ML and the plurality of switching elements SE, the plurality of pixel blocks PB may not operate during the first period S1. However, embodiments of the present disclosure are not limited thereto.

Next, during a second period S2, the second level shift LS2 transmits a low-level signal to the first mux signal line ML1. Further, during the second period S2, in response to the mode signal received from the mode controller MC, the first level shift LS1 transmits low-level signals to the first-first mode signal link line LL1-1, the first-second mode signal link line LL1-2, the first-third mode signal link line LL1-3, and the first-fourth mode signal link line LL1-4 and transmits high-level signals to the second-first mode signal link line LL2-1, the second-second mode signal link line LL2-2, the second-third mode signal link line LL2-3, and the second-fourth mode signal link line LL2-4.

Therefore, during the second period S2, all the plurality of pixel blocks PB, which are disposed in the first row, can operate as the pixel blocks PBS in the first mode (e.g., sharing view mode having a wide viewing angle) as the low-level signals are transmitted to the first-first mode signal link line LL1-1, the first-second mode signal link line LL1-2, the first-third mode signal link line LL1-3, and the first-fourth mode signal link line LL1-4.

Next, during a third period S3, the second level shift LS2 transmits a low-level signal to the second mux signal line ML2. Further, during the third period S3, in response to the mode signal received from the mode controller MC, the first level shift LS1 transmits low-level signals to the first-first mode signal link line LL1-1, the second-second mode signal link line LL2-2, the second-third mode signal link line LL2-3, and the first-fourth mode signal link line LL1-4 and transmits high-level signals to the second-first mode signal link line LL2-1, the first-second mode signal link line LL1-2, the first-third mode signal link line LL1-3, and the second-fourth mode signal link line LL2-4.

Therefore, during the third period S3, as the low-level signals are transmitted to the first-first mode signal link line LL1-1, the second-second mode signal link line LL2-2, the second-third mode signal link line LL2-3, and the first-fourth mode signal link line LL1-4, the plurality of pixel blocks PB disposed in the second row can operate such that the pixel block PB disposed in the second row and the first column can operate as the pixel block PBS in the first mode (e.g., sharing view mode having a wide viewing angle), the pixel block PB disposed in the second row and the second column can operate as the pixel block PBP in the second mode (e.g., privacy view mode having a narrow viewing angle), the pixel block PB disposed in the second row and the third column can operate as the pixel block PBP in the second mode (e.g., privacy view mode having a narrow viewing angle), and the pixel block PB disposed in the second row and the fourth column can operate as the pixel block PBS in the first mode (e.g., sharing view mode having a wide viewing angle).

Further, during a fourth period S4, the second level shift LS2 transmits a low-level signal to the third mux signal line ML3. Further, during the fourth period S4, in response to the mode signal received from the mode controller MC, the first level shift LS1 transmits low-level signals to the first-first mode signal link line LL1-1, the second-second mode signal link line LL2-2, the second-third mode signal link line LL2-3, and the first-fourth mode signal link line LL1-4 and transmits high-level signals to the second-first mode signal link line LL2-1, the first-second mode signal link line LL1-2, the first-third mode signal link line LL1-3, and the second-fourth mode signal link line LL2-4.

Therefore, during the fourth period S4, as the low-level signals are transmitted to the first-first mode signal link line LL1-1, the second-second mode signal link line LL2-2, the second-third mode signal link line LL2-3, and the first-fourth mode signal link line LL1-4, the plurality of pixel blocks PB disposed in the third row can operate such that the pixel block PB disposed in the third row and the first column can operate as the pixel block PBS in the first mode (e.g., sharing view mode having a wide viewing angle), the pixel block PB disposed in the third row and the second column can operate as the pixel block PBP in the second mode (e.g., privacy view mode having a narrow viewing angle), the pixel block PB disposed in the third row and the third column can operate as the pixel block PBP in the second mode (e.g., privacy view mode having a narrow viewing angle), and the pixel block PB disposed in the third row and the fourth column can operate as the pixel block PBS in the first mode (e.g., sharing view mode having a wide viewing angle).

Next, during a fifth period S5, the second level shift LS2 transmits a low-level signal to the fourth mux signal line ML4. Further, during the fifth period S5, in response to the mode signal received from the mode controller MC, the first level shift LS1 transmits low-level signals to the first-first mode signal link line LL1-1, the first-second mode signal link line LL1-2, the first-third mode signal link line LL1-3, and the first-fourth mode signal link line LL1-4 and transmits high-level signals to the second-first mode signal link line LL2-1, the second-second mode signal link line LL2-2, the second-third mode signal link line LL2-3, and the second-fourth mode signal link line LL2-4.

Therefore, as illustrated in FIG. 9, during the first to fifth periods, among the sixteen pixel blocks PB in the display device 100, four pixel blocks PBP at the central portion can operate in the second mode (e.g., privacy view mode having a narrow viewing angle), and the remaining pixel blocks PBS can operate in the first mode (e.g., sharing view mode having a wide viewing angle).

Next, as illustrated in FIG. 11, among the sixteen pixel blocks PB in the display device 100, the four pixel blocks PB, which are disposed in the first row and the first column, the second row and the second column, the third row and the third column, and the fourth row and the fourth column, can operate as the pixel blocks PBP in the second mode, and the remaining pixel blocks PB can operate as the pixel blocks PBS in the first mode.

With reference to FIG. 12 together, the mode controller MC generates the synchronizing signal V_sync that can separate the plurality of periods S1 to S5. The synchronizing signal V_sync can be generated once for one frame.

First, during the first period S1, the first level shift LS1 transmits low-level signals to the first-first mode signal link line LL1-1, the first-second mode signal link line LL1-2, the first-third mode signal link line LL1-3, and the first-fourth mode signal link line LL1-4 and transmits high-level signals to the second-first mode signal link line LL2-1, the second-second mode signal link line LL2-2, the second-third mode signal link line LL2-3, and the second-fourth mode signal link line LL2-4. However, during the first period S1, because the mux signals are not transmitted from the second level shift LS2 to the plurality of mux signal lines ML and the plurality of switching elements SE, the plurality of pixel blocks PB may not operate during the first period S1. However, embodiments of the present disclosure are not limited thereto.

Next, during the second period S2, the second level shift LS2 transmits a low-level signal to the first mux signal line ML1. Further, during the second period S2, in response to the mode signal received from the mode controller MC, the first level shift LS1 transmits low-level signals to the second-first mode signal link line LL2-1, the first-second mode signal link line LL1-2, the first-third mode signal link line LL1-3, and the first-fourth mode signal link line LL1-4 and transmits high-level signals to the first-first mode signal link line LL1-1, the second-second mode signal link line LL2-2, the second-third mode signal link line LL2-3, and the second-fourth mode signal link line LL2-4.

Therefore, during the second period S2, as the low-level signals are transmitted to the second-first mode signal link line LL2-1, the first-second mode signal link line LL1-2, the first-third mode signal link line LL1-3, and the first-fourth mode signal link line LL1-4, the plurality of pixel blocks PB disposed in the first row can operate such that the pixel block PB disposed in the first row and the first column can operate as the pixel block PBP in the second mode (e.g., privacy view mode having a narrow viewing angle), and the pixel blocks PB disposed in the first row and the second column, the first row and the third column, and the first row and the fourth column can operate as the pixel blocks PBS in the first mode (e.g., sharing view mode having a wide viewing angle).

Next, during the third period S3, the second level shift LS2 transmits a low-level signal to the second mux signal line ML2. Further, during the second period S3, in response to the mode signal received from the mode controller MC, the first level shift LS1 can transmit low-level signals to the first-first mode signal link line LL1-1, the second-second mode signal link line LL2-2, the first-third mode signal link line LL1-3, and the first-fourth mode signal link line LL1-4 and transmit high-level signals to the second-first mode signal link line LL2-1, the first-second mode signal link line LL1-2, the second-third mode signal link line LL2-3, and the second-fourth mode signal link line LL2-4.

Therefore, during the third period S3, as the low-level signals are transmitted to the first-first mode signal link line LL1-1, the second-second mode signal link line LL2-2, the first-third mode signal link line LL1-3, and the first-fourth mode signal link line LL1-4, the plurality of pixel blocks PB disposed in the second row can operate such that the pixel block PB disposed in the second row and the first column can operate as the pixel block PBS in the first mode (e.g., sharing view mode having a wide viewing angle), the pixel block PB disposed in the second row and the second column can operate as the pixel block PBP in the second mode (e.g., privacy view mode having a narrow viewing angle), the pixel block PB disposed in the second row and the third column can operate as the pixel block PBS in the first mode (e.g., sharing view mode having a wide viewing angle), and the pixel block PB disposed in the second row and the fourth column can operate as the pixel block PBS in the first mode (e.g., sharing view mode having a wide viewing angle).

Further, during the fourth period S4, the second level shift LS2 transmits a low-level signal to the third mux signal line ML3. Further, during the fourth period S4, in response to the mode signal received from the mode controller MC, the first level shift LS1 transmits low-level signals to the first-first mode signal link line LL1-1, the first-second mode signal link line LL1-2, the second-third mode signal link line LL2-3, and the first-fourth mode signal link line LL1-4 and transmits high-level signals to the second-first mode signal link line LL2-1, the second-second mode signal link line LL2-2, the first-third mode signal link line LL1-3, and the second-fourth mode signal link line LL2-4.

Therefore, during the fourth period S4, as the low-level signals are transmitted to the first-first mode signal link line LL1-1, the first-second mode signal link line LL1-2, the second-third mode signal link line LL2-3, and the first-fourth mode signal link line LL1-4, the pixel block PB disposed in the third row and the first column can operate as the pixel block PBS in the first mode (e.g., sharing view mode having a wide viewing angle), the pixel block PB disposed in the third row and the second column can operate as the pixel block PBS in the first mode (e.g., sharing view mode having a wide viewing angle), the pixel block PB disposed in the third row and the third column can operate as the pixel block PBP in the second mode (e.g., privacy view mode having a narrow viewing angle), and the pixel block PB disposed in the third row and the fourth column can operate as the pixel block PBS in the first mode (e.g., sharing view mode having a wide viewing angle).

Next, during the fifth period S5, the second level shift LS2 transmits a low-level signal to the fourth mux signal line ML4. Further, during the fifth period S5, in response to the mode signal received from the mode controller MC, the first level shift LS1 transmits low-level signals to the first-first mode signal link line LL1-1, the first-second mode signal link line LL1-2, the first-third mode signal link line LL1-3, and the second-fourth mode signal link line LL2-4 and transmits high-level signals to the second-first mode signal link line LL2-1, the second-second mode signal link line LL2-2, the second-third mode signal link line LL2-3, and first-fourth mode signal link line LL2-4.

Therefore, during the fifth period S5, as the low-level signals are transmitted to the first-first mode signal link line LL1-1, the first-second mode signal link line LL1-2, the first-third mode signal link line LL1-3, and the second-fourth mode signal link line LL2-4, the plurality of pixel blocks PB disposed in the fourth row connected to the fourth mux signal line ML4 can operate such that the pixel block PB disposed in the fourth row and the first column can operate as the pixel block PBS in the first mode (e.g., sharing view mode having a wide viewing angle), the pixel block PB disposed in the fourth row and the second column can operate as the pixel block PBS in the first mode (e.g., privacy view mode having a narrow viewing angle), the pixel block PB disposed in the fourth row and the third column can operate as the pixel block PBS in the first mode (e.g., sharing view mode having a wide viewing angle), and the pixel block PB disposed in the fourth row and the fourth column can operate as the pixel block PBP in the second mode (e.g., privacy view mode having a narrow viewing angle).

Therefore, during the first to fifth periods, as illustrated in FIG. 11, among the sixteen pixel blocks PB in the display device 100, the four pixel blocks PB, which are disposed in the first row and the first column, the second row and the second column, the third row and the third column, and the fourth row and the fourth column, can operate as the pixel blocks PBP in the second mode (e.g., privacy view mode having a narrow viewing angle), and the remaining pixel blocks PB can operate as the pixel blocks PBS in the first mode (e.g., sharing view mode having a wide viewing angle).

Depending on the user's needs, the display device can use a technology for selectively controlling the plurality of areas of the display panel as one of the area, in which the first viewing angle is defined and the operation is performed in the first mode, and the area in which the second viewing angle smaller than the first viewing angle is defined and the operation is performed in the second mode. Therefore, the first and second mode lines are connected to the plurality of areas of the display panel, and any one of the first and second mode signals is selectively transmitted to each of the plurality of areas, such that the mode of each of the plurality of areas can be selectively controlled. For example, the user can designate certain portions of the display screen to operate in the privacy viewing mode while remaining portions can be designated to operate in the share viewing mode, and the user can dynamically change the modes of different portions of the screen on a pixel-block by pixel-block basis, as desired, which can increase user convenience.

In the situation that the plurality of areas connected to the first and second mode lines are disposed only in one direction in the display device while corresponding to the directions in which the first and second mode lines are disposed, the viewing angle of each of the plurality of areas can be adjusted only in one direction. Therefore, a degree of freedom related to the mode selection for each of the plurality of areas of the display panel can be reduced.

In this situation, in the situation that m areas of the display panel are disposed in the row direction (m is a positive integer), m first mode lines and m second mode lines are required. Therefore, a total of 2 m signals can be needed to selectively control the mode of each of the plurality of areas of the display panel. However, for example, in the situation that in the display panel, n areas are disposed in the row direction and m areas are disposed in the column direction (m and n are positive integers) to more freely select the mode of each of the plurality of areas of display panel, (m×n) first mode lines and (m×n) second mode lines are used. Therefore, a total of (2×m×n) signals can be used to selectively control the mode of each of the plurality of areas of the display panel on a pixel-block by pixel-block basis.

Therefore, in the situation that it is desirable to control the modes of the plurality of areas of the display panel in both the row direction and the column direction on a pixel-block by pixel-block basis, there can occur a problem in that the number of control signals is remarkably increased in comparison with the situation in which the modes of the plurality of areas disposed only in one direction are controlled. In addition, as the number of areas is increased to improve the resolution of the display panel, the number of control signals and the number of lines for transmitting control signals can be more rapidly increased.

The display device 100 according to an embodiment of the present disclosure can be configured such that the mode of each of the plurality of pixel blocks PB can be selected in both the row direction and the column direction pixel-block by pixel-block basis. Therefore, in the display device 100 according to an embodiment of the present specification, a degree of freedom related to the selection of the viewing angle mode for each of the plurality of pixel blocks PB can be improved, and the convenience of the display device 100 can be improved.

In addition, in the display device 100 according to an embodiment of the present specification, the plurality of mux parts MUX, which corresponds to the column of each of the plurality of pixel blocks PB, can be disposed, which can minimize the number of signals for controlling the modes of the plurality of pixel blocks PB and the number of lines for transmitting the corresponding signals. In this way, the amount of wiring can be reduced and power consumption can be reduced.

In the display device 100 according to an embodiment of the present disclosure, n pixel blocks PB can be disposed in the row direction, and m pixel blocks PB can be disposed in the column direction. Further, the plurality of mux parts MUX can be connected to the first level shift LS1, which transmit the first mode signal or second mode signal related to mode of the plurality of pixel blocks PB to the plurality of mux parts MUX, and connected to the second level shift LS2 that time-divides the signal, which is received from the mode controller MC, and transmits the plurality of mux signals to the plurality of mux parts MUX. Therefore, the plurality of mux parts MUX can be configured to control the modes of the plurality of pixel blocks PB in collective response to the mode signal transmitted from the first level shift LS1 and the mux signal transmitted from the second level shift LS2. In this situation, the number of mode signals transmitted from the first level shift LS1 to the plurality of mux parts MUX is 2n, and the number of mux signals transmitted from the second level shift LS2 to the plurality of mux parts MUX is m. That is, in the embodiment, because the total number of signals for controlling the modes of the plurality of pixel blocks PB, which is disposed such that n pixel blocks PB are disposed in the row direction and m pixel blocks PB are disposed in the column direction, is (2n+m), the number of control signals is decreased to (2n+m) in comparison with the situation in which the number of signals, which is required when the first and second mode signal lines are disposed on the plurality of pixel blocks disposed such that n pixel blocks are disposed in the row direction and m pixel blocks are disposed in the column direction, is (2×m×n). Therefore, the number of control signals and the number of lines for transmitting the control signals can be minimized. Therefore, in the display device 100 according to an embodiment of the present disclosure, the plurality of mux parts MUX, which correspond to the column of each of the plurality of pixel blocks PB, can be disposed, which can minimize the number of signals for controlling the modes of the plurality of pixel blocks PB. Therefore, it is possible to provide the high-efficiency, reduced wiring that save space, low-power display device with reduced power consumption.

The example embodiments of the present disclosure can also be described as follows below.

According to an aspect of the present disclosure, a display device can include a plurality of pixel blocks each having a plurality of pixels, a plurality of mux parts disposed to correspond to a column of each of the plurality of pixel blocks, a first level shift configured to transmit a first mode signal or second mode signal related to mode of the plurality of pixel blocks to the plurality of mux parts, a second level shift configured to transmit a plurality of mux signals to the plurality of mux parts, and a mode controller configured to control the first level shift and the second level shift.

The plurality of mux parts each can include a plurality of switching elements connected to rows of the plurality of pixel blocks in one column of the plurality of pixel blocks.

The plurality of switching elements can include a plurality of first switching elements connected to the plurality of pixel blocks and configured to transmit the first mode signal, and a plurality of second switching elements connected to the plurality of pixel blocks and configured to transmit the second mode signal.

When the plurality of pixel blocks are disposed in m rows and n columns, the number of mux parts is n, the number of first switching elements can be (m×n), the number of second switching elements can be (m×n), and n and m can be positive integers.

The display device can further include a plurality of first mode signal link lines configured to connect the plurality of first switching elements and the first level shift, and a plurality of second mode signal link lines configured to connect the plurality of second switching elements and the first level shift.

The display device can further include a plurality of first mode signal lines configured to connect the plurality of first switching elements and the plurality of pixel blocks, and a plurality of second mode signal lines configured to connect the plurality of second switching elements and the plurality of pixel blocks.

The display device can further include a plurality of mux signal lines configured to connect the plurality of switching elements and the second level shift.

When the plurality of pixel blocks can be disposed in m rows and n columns, the number of mux signal lines can be m.

Each of the plurality of pixels can include a first light-emitting element configured to be operated in response to a first mode signal transmitted from the first level shift, and a second light-emitting element configured to be operated in response to a second mode signal transmitted from the first level shift.

The display device can further include a first lens disposed on the first light-emitting element and having a viewing angle of a first value, and a second lens disposed on the second light-emitting element and having a viewing angle of a second value lower than the viewing angle of the first value.

According to another aspect of the present disclosure, a display device can include a plurality of pixel blocks each comprising a plurality of pixels and disposed in m rows and n columns, first to n-th mux parts disposed to correspond to the column of each of the plurality of pixel blocks, a first level shift configured to transmit a first mode signal or second mode signal related to mode of the plurality of pixel blocks to the first to n-th mux parts, a second level shift configured to transmit first to m-th mux signals to the first to n-th mux parts, and a mode controller configured to control the first level shift and the second level shift, n and m can be positive integers.

The first to n-th mux parts each can include a plurality of switching elements connected to rows of the plurality of pixel blocks in one column of the plurality of pixel blocks.

The plurality of switching elements can include a plurality of first switching elements connected to the plurality of pixel blocks and configured to transmit the first mode signal, and a plurality of second switching elements connected to the plurality of pixel blocks and configured to transmit the second mode signal.

The display device can further include a plurality of first mode signal link lines configured to connect the plurality of first switching elements and the first level shift, and a plurality of second mode signal link lines configured to connect the plurality of second switching elements and the first level shift.

The display device can further include a plurality of first mode signal lines configured to connect the plurality of first switching elements and the plurality of pixel blocks; and a plurality of second mode signal lines configured to connect the plurality of second switching elements and the plurality of pixel blocks.

The number of first switching elements can be (m×n), and the number of second switching elements can be (m×n).

The display device can further include first to n-th mux signal lines configured to connect the plurality of switching elements and the second level shift.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a plurality of pixel blocks, each of the plurality of pixel blocks including a plurality of pixels;
a plurality of mux parts disposed to correspond to columns of the plurality of pixel blocks;
a first level shift configured to transmit a first mode signal or a second mode signal to the plurality of mux parts;
a second level shift configured to transmit a plurality of mux signals to the plurality of mux parts; and
a mode controller configured to control the first level shift and the second level shift.

2. The display device of claim 1, wherein each of the plurality of mux parts includes a plurality of switching elements connected to rows of the plurality of pixel blocks in one column of the plurality of pixel blocks.

3. The display device of claim 2, wherein the plurality of switching elements include:
a plurality of first switching elements connected to the plurality of pixel blocks and configured to transmit the first mode signal; and
a plurality of second switching elements connected to the plurality of pixel blocks and configured to transmit the second mode signal.

4. The display device of claim 3, wherein the plurality of pixel blocks are disposed in m rows and n columns, a number of the plurality of mux parts is n, a number of the plurality of first switching elements is m×n, a number of the plurality of second switching elements is m×n, and n and m are positive integers.

5. The display device of claim 3, further comprising:
a plurality of first mode signal link lines configured to connect the plurality of first switching elements with the first level shift; and
a plurality of second mode signal link lines configured to connect the plurality of second switching elements with the first level shift.

6. The display device of claim 3, further comprising:
a plurality of first mode signal lines configured to connect the plurality of first switching elements with the plurality of pixel blocks; and
a plurality of second mode signal lines configured to connect the plurality of second switching elements with the plurality of pixel blocks.

7. The display device of claim 2, further comprising:
a plurality of mux signal lines configured to connect the plurality of switching elements with the second level shift.

8. The display device of claim 7, wherein the plurality of pixel blocks are disposed in m rows and n columns, a number of the plurality of mux signal lines is m, and n and m are positive integers.

9. The display device of claim 1, wherein each of the plurality of pixels includes:
a first light-emitting element configured to emit light in response to a first mode signal transmitted from the first level shift; and
a second light-emitting element configured to emit light in response to a second mode signal transmitted from the first level shift.

10. The display device of claim 9, further comprising:
a first lens disposed on the first light-emitting element and having a viewing angle of a first value; and
a second lens disposed on the second light-emitting element and having a viewing angle of a second value lower than the viewing angle of the first value.

11. A display device comprising:
a plurality of pixel blocks disposed in m rows and n columns, each of the plurality of pixel blocks including a plurality of pixels, and n and m being positive integers;
first to n-th mux parts disposed to correspond to a column of the plurality of pixel blocks;
a first level shift configured to transmit a first mode signal or second mode signal to the first to n-th mux parts;
a second level shift configured to transmit first to m-th mux signals to the first to n-th mux parts; and
a mode controller configured to control the first level shift and the second level shift.

12. The display device of claim 11, wherein each of the first to n-th mux parts includes a plurality of switching elements connected to rows of the plurality of pixel blocks in one column of the plurality of pixel blocks.

13. The display device of claim 12, wherein the plurality of switching elements include:
a plurality of first switching elements connected to the plurality of pixel blocks and configured to transmit the first mode signal; and
a plurality of second switching elements connected to the plurality of pixel blocks and configured to transmit the second mode signal.

14. The display device of claim 13, further comprising:
a plurality of first mode signal link lines configured to connect the plurality of first switching elements with the first level shift; and
a plurality of second mode signal link lines configured to connect the plurality of second switching elements with the first level shift.

15. The display device of claim 13, further comprising:
a plurality of first mode signal lines configured to connect the plurality of first switching elements with the plurality of pixel blocks; and
a plurality of second mode signal lines configured to connect the plurality of second switching elements with the plurality of pixel blocks.

16. The display device of claim 13, wherein a number of the plurality of first switching elements is m×n, and a number of the plurality of second switching elements is m×n.

17. The display device of claim 12, further comprising:
first to n-th mux signal lines configured to connect the plurality of switching elements with the second level shift.

18. A display device comprising:
a display panel including a plurality of pixel blocks, each of the plurality of pixel blocks including a plurality of first type subpixels each including a first light emitting element configured to emit a same color light with a wide viewing angle, and a plurality of second type subpixels each including a second light emitting element configured to emit the same color light with a narrow viewing angle smaller than the wide viewing angle; and
a controller configured to:
supply a first mode signal to at least one pixel block among the plurality of pixel blocks and activate the plurality of first type subpixels within the at least one pixel block to emit the same color light with the wide viewing angle, and
supply a second mode signal to at least one other pixel block among the plurality of pixel blocks and activate the plurality of second type subpixels within the at least one other pixel block to emit the same color light with the narrow viewing angle.

19. The display device of claim 18, further comprising:
a plurality of mux parts connected between the controller and the plurality of pixel blocks, the plurality of max parts including a plurality of first switching elements and a plurality of second switching elements,
wherein the plurality of pixel blocks are disposed in m rows and n columns, a number of the plurality of mux parts is n, a number of the plurality of first switching elements is m×n, a number of the plurality of second switching elements is m×n, and n and m are positive integers.

20. The display device of claim 18, wherein the controller is further configured to:
selectively control the plurality of pixel blocks to operate in a first mode corresponding to the wide viewing angle or a second mode corresponding to the narrow viewing angle on a pixel-block by pixel block basis.

21. The display device of claim 18, further comprising:
a hemispherical shaped lens disposed over the first light emitting element; and
a semi-cylindrical shaped lens disposed over the second light emitting element.
